(19) United States
(12) Patent Application Publication
(10) Pub. No.: US 2024/0258414 A1
(43) Pub. Date: Aug. 1, 2024

(54) SEMICONDUCTOR DEVICE AND METHOD FOR MANUFACTURING THE SAME

(71) Applicant: Samsung Electronics Co., Ltd., Suwon-si (KR)

(72) Inventors: Minju AHN, Suwon-si (KR); JONGMIN SHIN, Suwon-si (KR)

(21) Appl. No.: 18/226,606

(22) Filed: Jul. 26, 2023

(30) Foreign Application Priority Data
Jan. 31, 2023 (KR) 10-2023-0012896

(51) Int. Cl. H01L 29/775; H01L 29/06; H01L 29/423; H01L 29/66

(52) U.S. Cl. CPC H01L 29/775; H01L 29/0673; H01L 29/42392; H01L 29/66439

(57) ABSTRACT

A semiconductor device including a substrate; active patterns positioned on the substrate; a first isolation layer and a second isolation layer positioned between the active patterns; a first protection liner positioned on the first isolation layer; a second protection liner positioned on the second isolation layer; channel patterns positioned on the active patterns: source/drain patterns positioned on both sides of the channel patterns; and a first gate electrode positioned above the first protection liner and the second protection liner, and surrounding the channel patterns, wherein the first isolation layer has a first width, the second isolation layer has a second width wider than the first width, and a first height from the substrate to the first protection liner is greater than a second height from the substrate to the second protection liner.

### CROSS-REFERENCE TO RELATED APPLICATION

This application claims priority to and the benefit of Korean Patent Application No. 10-2023-0012896 filed in the Korean Intellectual Property Office on Jan. 31, 2023, the entire content of which is incorporated herein by reference.

### BACKGROUND

### 1. Field

The present disclosure relates to a semiconductor device and a manufacturing method thereof.

### 2. Description of the Related Art

A semiconductor is a material belonging to an intermediate region between a conductor and an insulator, and means a material that conducts electricity under predetermined conditions. Various semiconductor devices may be manufactured using this semiconductor material, and for example, memory devices and the like may be manufactured. These semiconductor devices may be used in various electronic devices.

According to the trend of down-size and higher integration of the electronic devices, it is necessary to finely form patterns constituting semiconductor devices. Defects such as short-circuiting between electrodes or wires made of these fine patterns may occur.

### SUMMARY

Aspects of the present disclosure are directed to a semiconductor device with improved reliability and a manufacturing method thereof.

A semiconductor device according to an embodiment includes: a substrate extending a first direction and a second direction perpendicular to the first direction; active patterns positioned on the substrate; a first isolation layer and a second isolation layer positioned between the active patterns; a first protection liner positioned on the first isolation layer; a second protection liner positioned on the second isolation layer; channel patterns positioned on the active patterns; source/drain patterns positioned on both sides of the channel patterns; and a first gate electrode positioned above the first protection liner and the second protection liner, and surrounding the channel patterns, wherein the first isolation layer has a first width in the second direction, the second isolation layer has a second width, in the second direction, wider than the first width, and a first height from the substrate to the first protection liner is greater than a second height from the substrate to the second protection liner.

A semiconductor device according to an embodiment includes: a substrate extending a first direction and a second direction perpendicular to the first direction; active patterns positioned on the substrate; isolation layers positioned between the active patterns; a protection layer positioned on the isolation layer; channel patterns positioned on the active patterns; source/drain patterns positioned on both sides of the channel patterns; and a first gate electrode positioned on the active pattern and the protection layer, and surrounding the channel patterns.

A semiconductor device according to an embodiment includes: a substrate extending a first direction and a second direction perpendicular to the first direction; active patterns positioned on the substrate; a first isolation layer and a second isolation layer positioned between the active patterns; a first recess disposed in the upper surface of the first isolation layer; a second recess disposed in the upper surface of the second isolation layer; a first protection liner covering the bottom surface of the first recess; a second protection liner covering the bottom surface of the second recess; channel patterns positioned on the active patterns; source/drain patterns positioned on both sides of the channel patterns; and a first gate electrode positioned above the first protection liner and the second protection liner and surrounding the channel patterns, wherein the first isolation layer has a first width in the second direction, the second isolation layer has a second width, in the second direction, wider than the first width, and the depth of the second recess is greater than the depth of the first recess.

According to embodiments, by forming the protection layer on the isolation layer configuring the semiconductor device, reliability of the semiconductor device may be improved.

### BRIEF DESCRIPTION OF THE DRAWINGS

FIG. 1 is a plan view showing a semiconductor device according to an embodiment.

FIG. 2A is a cross-sectional view taken along a line Y1-Y1′ of FIG. 1.

FIG. 2B is an enlarged cross-sectional view showing a region A1 of FIG. 2A.

FIG. 2C is a cross-sectional view taken along a line Y2-Y2′ of FIG. 1.

FIG. 2D is a cross-sectional view taken along a line X1-X1′ of FIG. 1.

FIG. 3 and FIG. 4 are cross-sectional views showing a semiconductor device according to an embodiment.

FIG. 5A and FIG. 5B are cross-sectional views showing a semiconductor device according to an embodiment.

FIG. 6A and FIG. 6B are cross-sectional views showing a semiconductor device according to an embodiment

FIG. 7A, FIG. 8A, FIG. 10A, FIG. 12A, FIG. 13A, FIG. 15A, FIG. 16A, and FIG. 17A are plan views sequentially showing a method of manufacturing a semiconductor device according to an embodiment.

FIG. 7B, FIG. 8B, FIG. 9, FIG. 10B, FIG. 11, FIG. 12B, FIG. 13B, FIG. 15B, FIG. 16B, and FIG. 17B are cross-sectional views taken a line Y1-Y1′ of each plan view.

FIG. 14 and FIG. 15C are cross-sectional views showing a semiconductor device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clarify the present disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

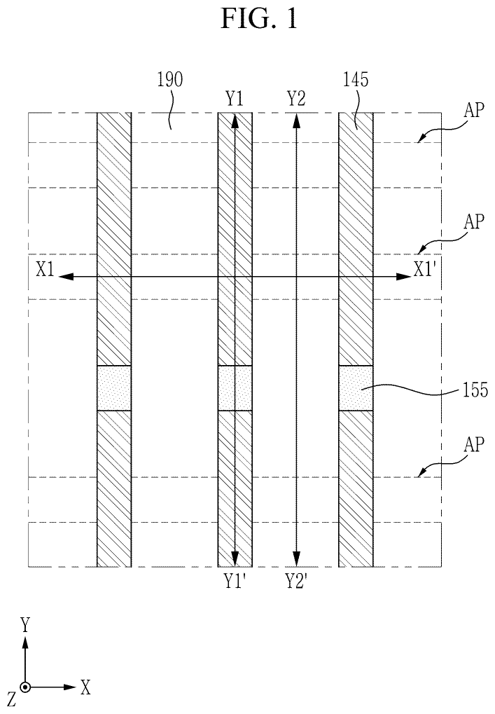

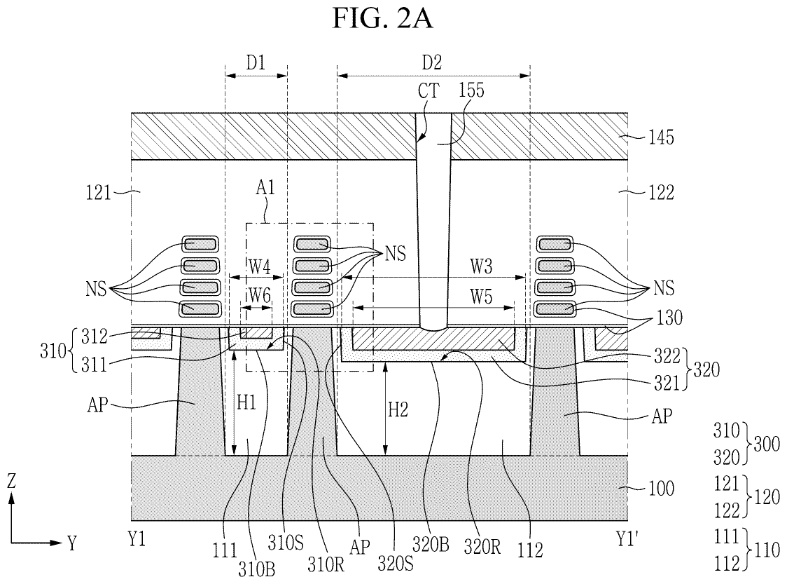

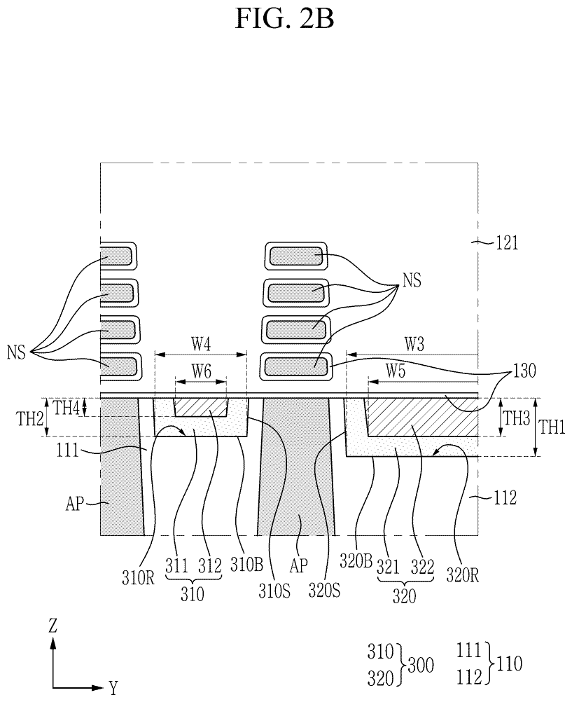

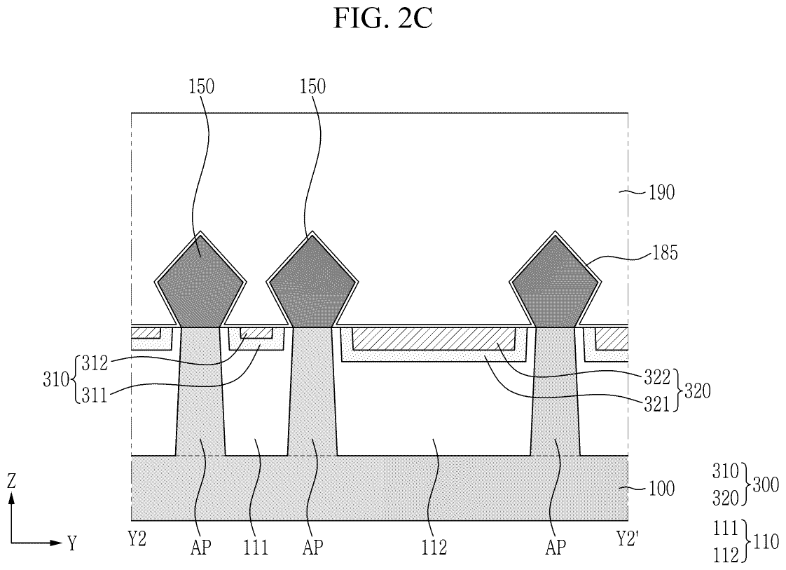

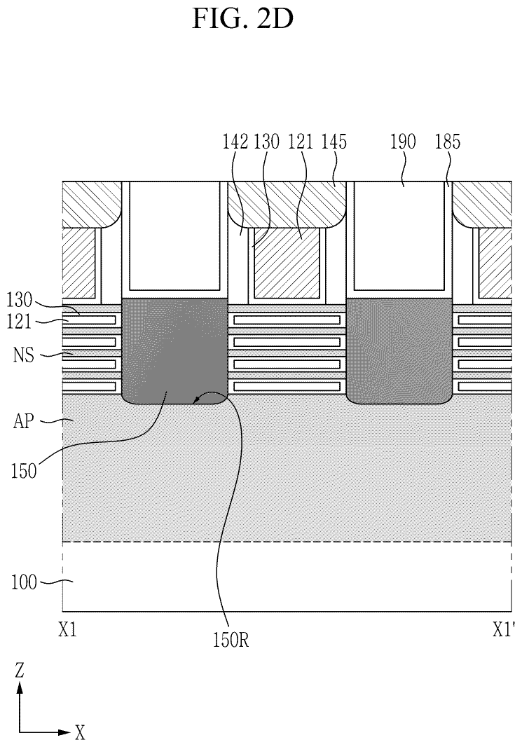

Hereinafter, a semiconductor device according to an embodiment is described with reference to FIG. 1 to FIG. 2D as follows.

FIG. 1 is a plan view showing a semiconductor device according to an embodiment. FIG. 2A is a cross-sectional view taken along a line Y1-Y1′ of FIG. 1. FIG. 2B is an enlarged cross-sectional view showing a region A1 of FIG. 2A. FIG. 2C is a cross-sectional view taken along a line Y2-Y2′ of FIG. 1. FIG. 2D is a cross-sectional view taken along a line X1-X1′ of FIG. 1.

A semiconductor device according to an embodiment includes a substrate 100, active patterns AP positioned on the substrate 100, isolation layers 110 positioned between the active patterns AP, a protection layer 300 positioned on the isolation layers 110, channel patterns NS positioned on the active patterns AP, gate electrodes 120 surrounding the channel patterns NS, source/drain patterns 150 disposed on both sides of the channel patterns NS, and an interlayer insulating layer 190 positioned on the source/drain patterns 150.

The substrate 100 may include a semiconductor material. For example, the substrate 100 may include a group IV semiconductor, a group III-V compound semiconductor, a group II-VI compound semiconductor, and the like. For example, the substrate 100 may include a semiconductor such as Si or Ge, or a compound semiconductor such as SiGe, SiC, GaAs, InAs, or InP. The substrate 100 may have a upper surface parallel to the first direction (the X direction) and the second direction (the Y direction) and a thickness parallel to a third direction (a Z direction) perpendicular to the first direction (the X direction) and the second direction (the Y direction).

On the substrate 100, active patterns AP may be positioned. The active patterns AP may protrude from the substrate 100. The active patterns AP may protrude in the third direction (the Z direction) from the upper surface of the substrate 100. The active patterns AP may be positioned to be spaced apart from each other along the second direction (the Y direction). The active patterns AP may extend along the first direction (the X direction).

The active patterns AP may be disposed by etching a portion of the substrate 100, or may include an epitaxial layer grown from the substrate 100. The active patterns AP may include semiconductors such as Si and Ge, and may include group IV semiconductors, group III-V compound semiconductors, group II-VI compound semiconductors, and the like.

The distance between the active patterns APs may not be constant. For the active patterns Aps may include a first active pattern, a second active pattern, and a third active pattern that extend along the first direction (the X direction) and are disposed to be spaced apart in the second direction (the Y direction). The distance, in the second direction, between the first active pattern and the second active pattern may be different from the distance between the second active pattern and the third active pattern. However, aspects of the present disclosure are not limited thereto, and the distance between the active patterns APs may be constant.

Channel patterns NS may be positioned on each of the active patterns AP. The channel patterns NS may be spaced apart from each of the active patterns AP in the third direction (the Z direction). It is shown that four channel patterns NS are disposed in the third direction (the Z direction), but it is not limited thereto.

The channel patterns NS may include the same material as the active patterns AP. For example, the channel patterns NS may include semiconductors such as Si and Ge, and may include a group IV semiconductor, a group III-V compound semiconductor, and a group II-VI compound semiconductor. However, without being limited thereto, the channel patterns NS may include different materials from the active patterns AP.

The widths of the channel patterns NS in the second direction (the Y direction) may be different. For example, the width of the channel patterns NS, stacked in the third direction (the Z direction), in the second direction (the Y direction) may decrease as the active patterns AP get farther away (e.g., as the distance increases from a top surface of the active patterns AP). However, it is not limited thereto, and the channel patterns NS may have the same width in the second direction (the Y direction).

The isolation layers 110 may be positioned on the substrate 100. The isolation layers 110 may be positioned between the active patterns AP. As described above, the distance between the active patterns AP may be different. Accordingly, the widths of the isolation layers 110 may be different. The width of the isolation layers 110 may mean the length along the second direction (the Y direction) of the bottom surface of the isolation layers 110. The width of the isolation layers 110 may correspond to the distance between the active patterns AP positioned on both sides of the isolation layers 110. The isolation layers 110 may have a shape whose width becomes narrower as it approaches substrate 100. Therefore, the width of the isolation layers 110 may mean the minimum length of the isolation layers 110 according to the second direction (the Y direction). The width of the isolation layers 110 positioned between the active patterns AP that are relatively closely spaced may be relatively narrow. The width of the isolation layers 110 positioned between the active patterns AP that are relatively distantly spaced may be relatively wide.

The isolation layers 110 may be disposed to cover the side surface of the active patterns AP. Although the isolation layers 110 are shown as covering the entire side surface of the active patterns AP, it is not limited thereto, and the isolation layers 110 may cover a part of the side surface of the active patterns AP. In this case, a part of the active patterns AP may protrude in the third direction (the Z direction) so as to extend beyond the upper surface of the isolation layers 110. The isolation layers 110, for example, may include silicon oxide (SiO2), silicon nitride (SiN), silicon oxynitride (SiON), or combinations thereof. The isolation layers 110 are illustrated as being a single film, but it is not limited thereto.

The isolation layers 110 may include a first isolation layer 111 having a first width D1 and a second isolation layer 112 having a second width D2. The second width D2 of the second isolation layer 112 may be wider (i.e., greater) than the first width D1 of the first isolation layer 111. The distance between the active patterns APs positioned on both sides of the second isolation layer 112 may be greater than the distance between the active patterns APs positioned on both sides of the first isolation layer 111.

A first recess 310R may be disposed on the upper surface of the first isolation layer 111. The first recess 310R may extend in the first direction (the X direction). The bottom surface 310B and the side surface 310s of the first recess 310R may be defined by the first isolation layer 111.

The first recess 310R defined by the first isolation layer 111 may have a shape whose width becomes narrower as the first recess 310R approaches the substrate 100. For example, the side surface 310S of the first recess 310R may have a shape similar to that of a reverse trapezoid. However, the width of the first recess 310R defined by the first isolation layer 111 may be constant without being limited thereto.

A second recess 320R may be disposed on an upper surface of the second isolation layer 112. The second recess 320R may extend in the first direction (the X direction). The bottom surface 320B and the side surface 320S of the second recess 320R may be defined by the second isolation layer 112.

The second recess 320R defined by the second isolation layer 112 may have a shape in which the width becomes narrower as the second recess 320R approaches the substrate 100. For example, the side surface 320S of the second recess 320R may have a shape similar to that of a reverse trapezoid. However, the width of the second recess 320R defined by the second isolation layer 112 may be constant without being limited thereto.

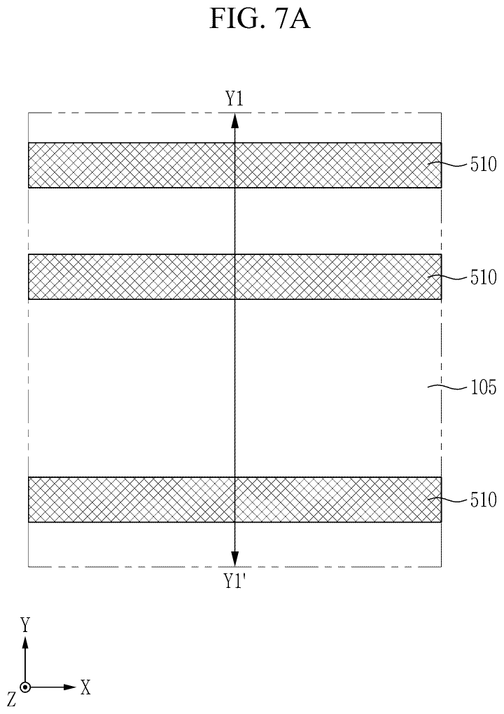

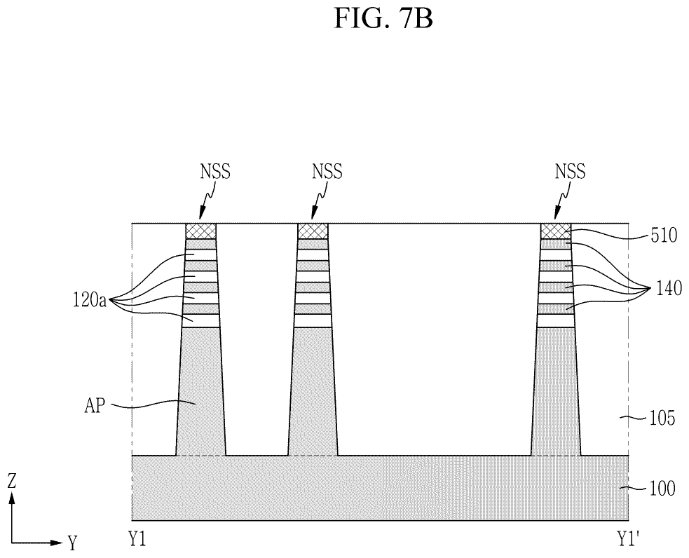

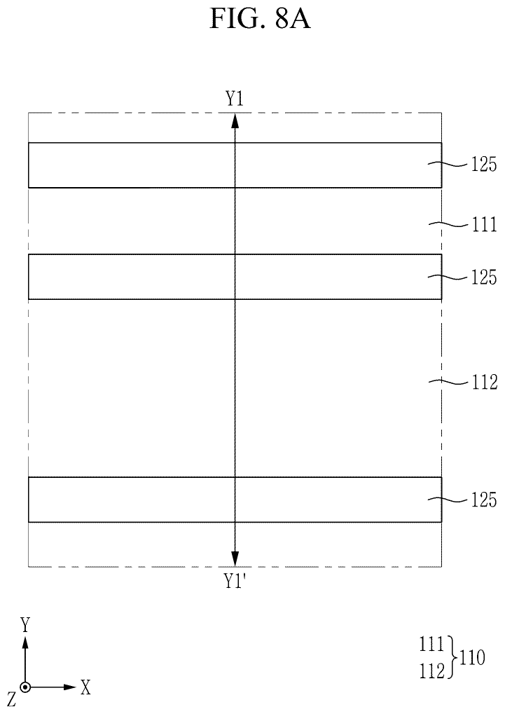

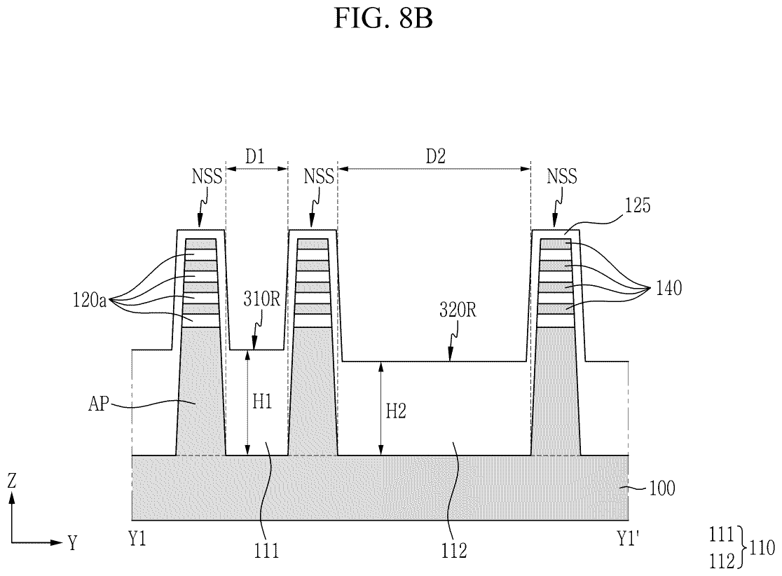

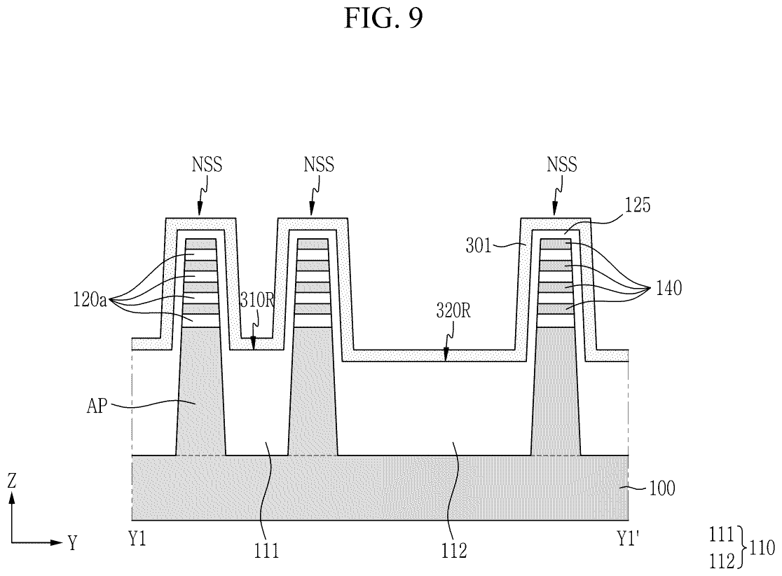

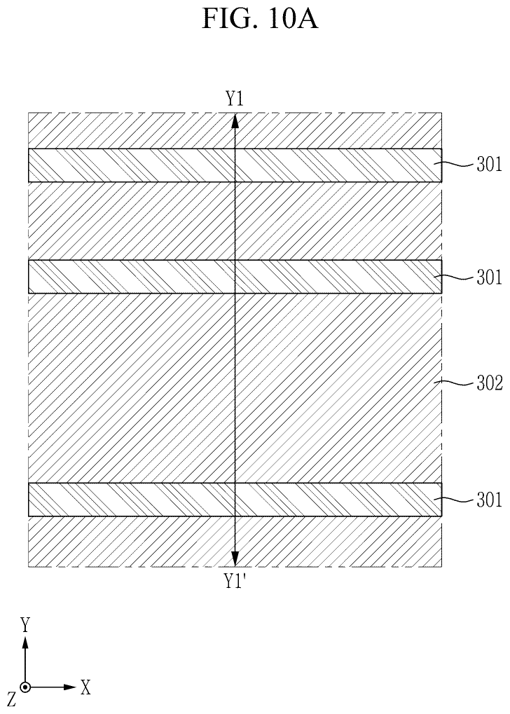

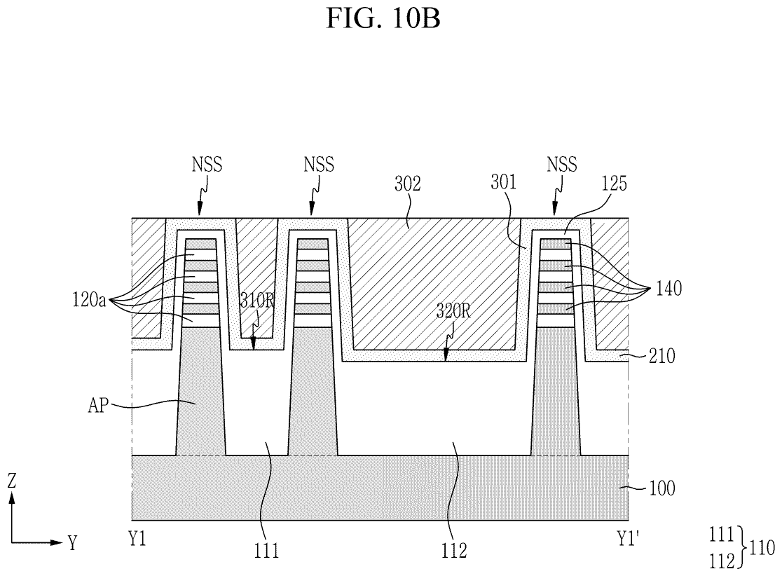

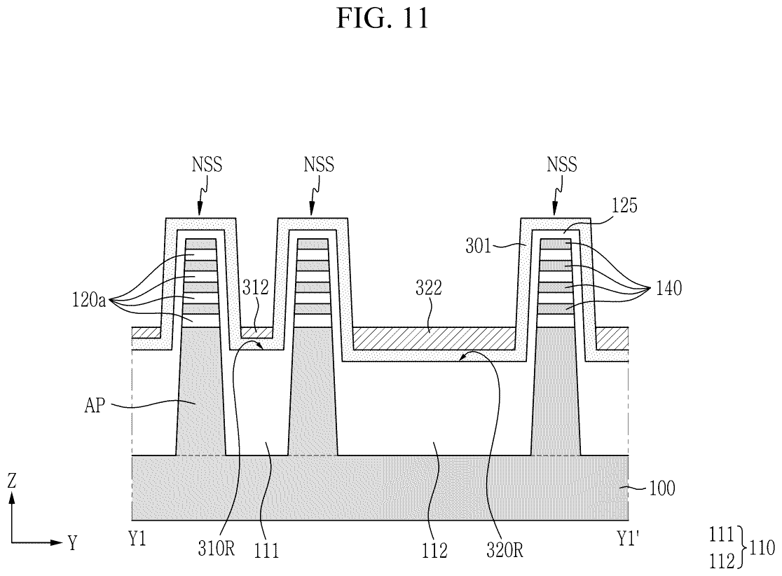

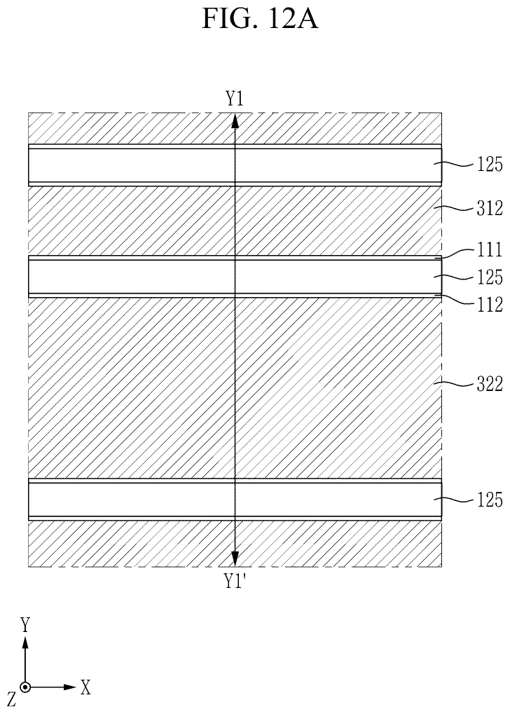

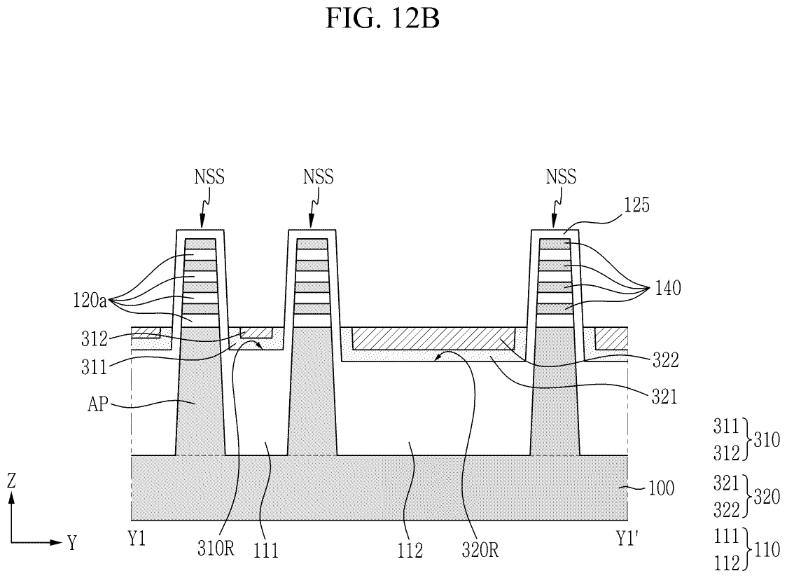

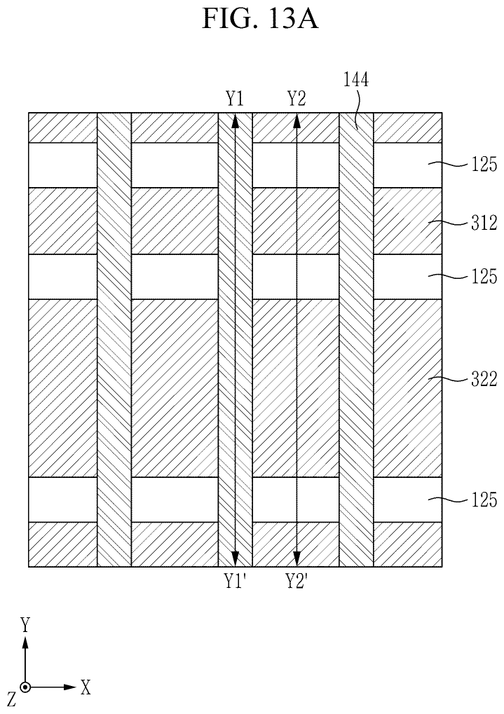

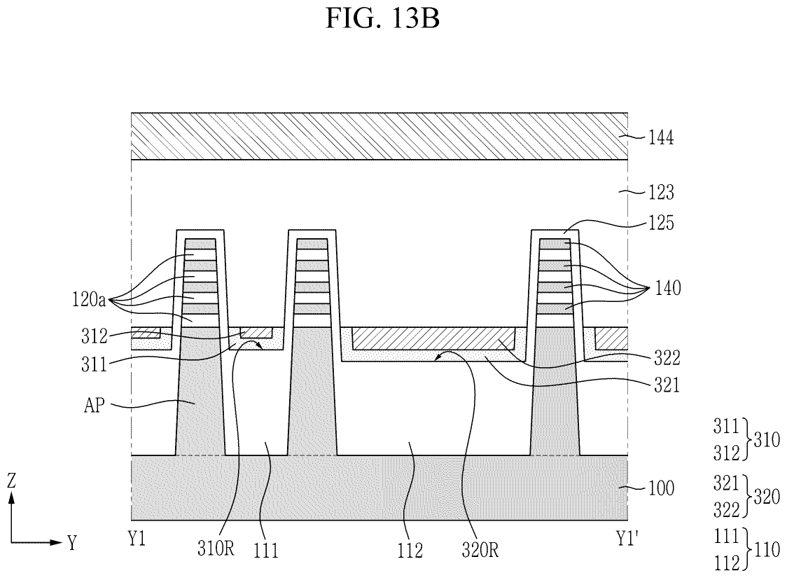

The bottom surface 320B of the second recess 320R may be lower than the bottom surface 310B of the first recess 310R. For example, the height from the substrate 100 to the first recess 310R may be higher (i.e., greater) than the height from the substrate 100 to the second recess 320R. Also, the width of the second recess 320R may be wider (i.e., greater) than the width of the first recess 310R, and the depth of the second recess 320R may be deeper (i.e., greater) than the depth of the first recess 310R. This may be due to a characteristic of the process of separating a preliminary isolation layer (105 in FIG. 7B) into a first isolation layer 111 and a second isolation layer 112 by etching. For example, since the second isolation layer 112 may have the relatively wider width than the first isolation layer 111, the second isolation layer 112 may be easily etched compared to the first isolation layer 111. Therefore, since the second isolation layer 112 may be etched with the wider width and depth than the first isolation layer 111, the width of the second recess 320R disposed by etching the second isolation layer 112 may be wider than the width of the first recess 310R disposed by etching the first isolation layer 111, and the depth of the second recess 320R may be deeper than the depth of the first recess 310R.

Here, the height of the first recess 310R and the height of the second recess 320R may be the minimum distances from the upper surface of the substrate 100 to the bottom surface 310B of the first recess 310R and the bottom surface 320B of the second recess 320R in the third direction (the Z direction), respectively.

On the isolation layers 110, the protection layer 300 is positioned. The protection layer 300 may be positioned in a recess disposed by removing a part of the isolation layers 110. The protection layer 300 may be positioned at the same level as a portion of the isolation layers 110. The upper surface of the protection layer 300 may be positioned at the same level as the upper surface of the active patterns AP. The protection layer 300 may include a first protection layer 310 positioned on the first isolation layer 111 and a second protection layer 320 positioned on the second isolation layer 112.

The first protection layer 310 may include a first protection liner 311 and a first protection insulation layer 312, and the second protection layer 320 may include a second protection liner 321 and a second protection insulation layer 322.

The first protection liner 311 may be positioned in the first recess 310R on the first isolation layer 111. The first protection liner 311 may extend along the profile of the first recess 310R. For example, the first protection liner 311 may extend along the bottom surface 310B of the first recess 310R and the side surface 310S of the first recess 310R. In addition, the first protection liner 311 may be conformally disposed along the profile of the first recess 310R. That is, the first protection liner 311 may be disposed with a constant thickness. The first protection liner 311 may be in contact with the first isolation layer 111. The first protection liner 311 may extend in the first direction (the X direction).

The second protection liner 321 may be positioned in the second recess 320R on the second isolation layer 112. The second protection liner 321 may extend along the profile of the second recess 320R. For example, the second protection liner 321 may extend along the bottom surface 320B of the second recess 320R and the side surface 320S of the second recess 320R. In addition, the second protection liner 321 may be conformally disposed along the profile of the second recess 320R. That is, the second protection liner 321 may be disposed with a constant thickness. The second protection liner 321 may be in contact with the second isolation layer 112. The second protection liner 321 may extend in the first direction (the X direction).

The first height H1 from the substrate 100 to the first protection liner 311 may be higher (i.e., greater) than the second height H2 from the substrate 100 to the second protection liner 321. Here, the first height H1 from the substrate 100 to the first protection liner 311 and the second height H2 from the substrate 100 to the second protection liner 321 may be the minimum distance from the upper surface of the substrate 100 to the bottom surface of the first protection liner 311 and the bottom surface of the second protection liner 321 in the third direction (the Z direction), respectively.

The third width W3 of the second protection liner 321 may be greater than the fourth width W4 of the first protection liner 311. As described above, the width of the second recess 320R may be wider than the width of the first recess 310R. Accordingly, the third width W3 of the second protection liner 321 disposed along the profile of the second recess 320R may be wider than the fourth width W4 of the first protection liner 311 disposed along the profile of the first recess 310R. Here, the third width W3 of the second protection liner 321 may mean the length along the second direction (the Y direction) of the bottom surface of the second protection liner 321, and the fourth width W4 of the first protection liner 311 may mean the length along the second direction (the Y direction) of the bottom surface of the first protection liner 311.

Also, as shown in FIG. 2B, the first depth TH1 of the second protection liner 321 may be deeper than the second depth TH2 of the first protection liner 311. As described above, the depth of the second recess 320R may be greater than the depth of the first recess 310R. Accordingly, the first depth TH1 of the second protection liner 321 disposed along the profile of the second recess 320R may be deeper than the second depth TH2 of the first protection liner 311 disposed along the profile of the first recess 310R. For example, the depth of the second recess 320R may correspond to the first depth TH1 of the second protection liner 321, and the depth of the first recess 310R may correspond to the second depth TH2 of the first protection liner 311. Here, the first depth TH1 of the second protection liner 321 may mean the length which the second protection liner 321 extends in the third direction (the Z direction), and the second depth TH2 of the first protection liner 311 may mean the length which the first protection liner 311 extends in the third direction (the Z direction).

The first protection liner 311 may include a material having different etch selectivity from that of the first isolation layer 111. The second protection liner 321 may include a material having a different etch selectivity from that of the second isolation layer 112. In addition, the first protection liner 311 and the second protection liner 321 may include a material having different etch selectivity from the channel patterns NS. For example, the first protection liner 311 and the second protection liner 321 may include silicon nitride (SiN). The first protection liner 311 and the second protection liner 321 may include the same material, but it is not limited thereto.

The first protection insulation layer 312 may be positioned on the first protection liner 311. The first protection insulation layer 312 may be disposed within the first recess 310R. The first protection insulation layer 312 may fill a portion of the first recess 310R that is not filled by the first protection liner 311. In addition, the second protection insulation layer 322 may be positioned on the second protection liner 321. The second protection insulation layer 322 may be disposed within the second recess 320R. The second protection insulation layer 322 may fill a portion of the second recess 320R that is not filled by the second protection liner 321.

The fifth width W5 of the second protection insulation layer 322 may be wider than the sixth width W6 of the first protection insulation layer 312. The third depth TH3 of the second protection insulation layer 322 may be deeper than the fourth depth TH4 of the first protection insulation layer 312. At this time, the fifth width W5 of the second protection insulation layer 322 may mean the length along the second direction (the Y direction) of the bottom surface of the second protection insulation layer 322, and the sixth width W6 of the first protection insulation layer 312 may mean the length of the bottom surface of the first protection insulation layer 312 in the second direction (the Y direction).

The upper surface of the first protection insulation layer 312 and the upper surface of the second protection insulation layer 322 may be positioned at the same level (i.e., in the third direction (the Z direction)). In addition, the upper surface of the first protection insulation layer 312 may be positioned at the same level as a portion of the first isolation layer 111, and the upper surface of the second protection insulation layer 322 may be positioned at the same level as a portion of the second isolation layer 112. As another example, the upper surface of the first protection insulation layer 312 may be higher than the upper surface of the second protection insulation layer 322.

The first protection insulation layer 312 may include a material having different etch selectivity from that of the first protection liner 311. The second protection insulation layer 322 may include a material having different etch selectivity from that of the second protection liner 321. Alternatively, the first protection insulation layer 312 and the second protection insulation layer 322 may include the same material as the isolation layers 110. The first protection insulation layer 312 and the second protection insulation layer 322, for example, may include or may be formed of silicon oxide (SiO2) silicon oxynitride (SiON) or combinations thereof. However, it is not limited thereto, the first protection insulation layer 312 and the second protection insulation layer 322 may include or may be formed of a material different from that of the isolation layers 110. The first protection insulation layer 312 and the second protection insulation layer 322 may include or may be formed of the same material as each other, but it is not limited thereto.

In the above, the protection layer 300 has been described as including the first protection insulation layer 312 and the second protection insulation layer 322, but it is not limited thereto. In some cases, the first protection insulation layer 312 and the second protection insulation layer 322 may be omitted. For example, the protection layer 300 may only include the first protection liner 311 and the second protection liner 321.

Gate electrodes 120 may be positioned on the substrate 100. The gate electrodes 120 may extend in the second direction (the Y direction). The gate electrodes 120 may be spaced apart in the first direction (the X direction), respectively. The gate electrodes 120 may cross the active patterns AP. The gate electrodes 120 may surround each of the channel patterns NS. The gate electrodes 120 may be positioned on the protection layer 300.

At least part of the gate electrodes 120 may be positioned on the stacking structure of the channel patterns NS. Another part of the gate electrodes 120 may be disposed to cover both sides of the stacking structure of the channel patterns NS. At this time, four surfaces of the channel patterns NS may be surrounded by the gate electrodes 120.

The gate electrodes 120 may include at least one of a metal, a metal alloy, a conductive metal nitride, a metal silicide, a doped semiconductor material, a conductive metal oxide, and a conductive metal oxynitride. The gate electrodes 120, for example, may include at least one among titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide (TiAlC—N), titanium aluminum carbide (TiAlC), titanium carbide (TiC), tantalum carbide (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but it is not limited thereto. The conductive metal oxide and the conductive metal oxynitride may include a shape in which the above materials are oxidized, but it is not limited thereto.

The gate electrodes 120 may be positioned on both sides of source/drain patterns 150 to be described later. For example, all of the gate electrodes 120 positioned on both sides of the source/drain patterns 150 may be electrodes used as gates of transistors.

The gate electrodes 120 may include a first gate electrode 121 and a second gate electrode 122. The first gate electrode 121 and the second gate electrode 122 may be separated by a gate separation structure 155.

The gate separation structure 155 may be positioned above the isolation layers 110. A plurality of gate separation structures 155 may be disposed to be spaced apart from each other along the first direction (the X direction), but is not limited thereto. The gate separation structure 155 may separate the first gate electrode 121 and the second gate electrode 122 aligned in the second direction (the Y direction). In the semiconductor device according to an embodiment, one gate separation structure 155 may separate a pair of first gate electrode 121 and a second gate electrode 122. That is, it is possible to prevent short-circuiting between the adjacent gate electrodes 120 by the gate separation structure 155.

The upper surface of the gate separation structure 155 may be positioned at a higher level than the upper surface of the gate electrodes 120. A capping layer 145 may be positioned on the gate electrodes 120, and the upper surface of the gate separation structure 155 may be positioned at the same level as an upper surface of the capping layer 145. For example, the upper surface of the gate separation structure 155 and the upper surface of the capping layer 145 may be substantially equivalent in the third direction (the Z direction).

The gate separation structure 155 may include, for example, silicon nitride (SiN), silicon oxynitride (SiON), silicon oxide (SiO2), silicon carbonate nitride (SiOCN), silicon boronnitride (SiBN), silicon oxyboron nitride (SiOBN), silicon carbonate (SiOC), aluminum oxide (AlO), and a combination thereof. The gate separation structure 155 is shown as being a single layer, but is not limited thereto.

The gate separation structure 155 may be in contact with the second protection insulation layer 322. In addition, the gate separation structure 155 may be also in contact with the gate insulating layer 130 extending in the second direction (the Y direction) along the lower surface of the gate electrodes 120. In FIG. 2A, the gate separation structure 155 is shown as being recessed into the second protection insulation layer 322, but is not limited thereto.

The gate insulating layer 130 may extend along the upper surface of the protection layer 300 and the upper surface of the active patterns AP. The gate insulating layer 130 may cover the channel patterns NS. The gate electrodes 120 are positioned on the gate insulating layer 130. The gate insulating layer 130 is positioned between the gate electrodes 120 and the channel patterns NS.

The gate insulating layer 130 may include silicon oxide (SiO2), silicon nitride (SiN), silicon oxynitride (SiON), or a high dielectric constant material having a higher dielectric constant than the silicon oxide. The high dielectric constant material, for example, one or more of boron nitride, hafnium oxide, hafnium silicon oxide, or hafnium aluminum oxide, however it is not limited thereto.

The source/drain patterns 150 may be disposed to cover both sides of the stacking structure of the gate electrodes 120 and the channel patterns NS. At this time, the source/drain patterns 150 may be positioned on both sides of the channel patterns NS along the first direction (the X direction). As shown in FIG. 2D, the source/drain patterns 150 may be disposed in the source/drain recess 150R. The source/drain patterns 150 may play a role of a source/drain of the transistor using the channel patterns NS as a channel region.

A gate spacer 142 may be positioned on the sidewall of the gate electrodes 120. In this case, the gate spacer 142 is not disposed on the sidewall of the first gate electrode 121 positioned between the active patterns AP and the channel patterns NS. The gate spacer 142 is not disposed on the sidewall of the first gate electrode 121 between the adjacent channel patterns NS in the third direction (the Z direction). Although not shown in the drawing, an inner spacer may be further positioned on the sidewall of the first gate electrode 121 between the channel patterns NS. In addition, the inner spacer may be positioned on the sidewall of the first gate electrode 121 between the active pattern AP and the channel pattern NS positioned at the bottom. That is, the inner spacer may be positioned between the first gate electrode 121 positioned between the channel patterns NS and between the lowest channel pattern NS and the active pattern AP, and the source/drain patterns 150. The inner spacer may include the same material as the gate spacer 142.

The gate spacer 142, for example, may include silicon nitride (SiN), silicon oxynitride (SiON), silicon oxide (SiO2), silicon carbonate nitride (SiOCN), silicon boronnitride (SiBN), silicon oxyboron nitride (SiOBN), silicon carbonate (SiOC), and combinations thereof.

The capping layer 145 may be positioned on the gate electrodes 120 and the gate spacer 142. The upper surface of the capping layer 145 may be on the same plane as the upper surface of the interlayer insulating layer 190. Unlike as shown, the capping layer 145 may be disposed between the gate spacers 142. That is, the gate spacer 142 may cover the side surface of the capping layer 145.

The capping layer 145 may include, for example, at least one of silicon nitride (SiN), silicon oxynitride (SiON), silicon carbide nitride (SiCN), silicon carbonate nitride (SiOCN), and a combination thereof.

An etch stop layer 185 may be positioned on the upper surface of the protection layer 300, the sidewall of the gate spacer 142, and the upper surface of the source/drain patterns 150. The etch stop layer 185, for example, may include at least one of silicon nitride (SiN), silicon oxynitride (SiON), silicon carbonate nitride (SiOCN), silicon boronnitride (SiBN), silicon oxyboronitride (SiOBN), silicon carbonate (SiOC), and combinations thereof.

An interlayer insulating layer 190 may be positioned on the etch stop layer 185. The interlayer insulating layer 190 may be disposed on the protection layer 300 and the source/drain patterns 150. The interlayer insulating layer 190 may not cover the upper surface of the capping layer 145. For example, the upper surface of the interlayer insulating layer 190 may be on the same plane as the upper surface of the capping layer 145.

The interlayer insulating layer 190 may include, for example, at least one of silicon oxide (SiO2), silicon nitride (SiN), silicon oxynitride (SiON), and low dielectric constant (low-k) material. The low dielectric constant (low-k) material, for example, may include Fluorinated TetraEthylOrthoSilicate (FTEOS), HydrogenSilsesQuioxane (HSQ), Bis-benzocyclobutene (BCB), tetramethylortho silicate (TMOS), or combinations thereof, but it is not limited thereto.

According to the semiconductor device according to an embodiment, the first isolation layer 111 and the second isolation layer 112 may have different widths. In addition, recesses having different widths and different depths may be disposed in the first isolation layer 111 and the second isolation layer 112, respectively. For example, the depth of the second recess 320R disposed in the second isolation layer 112 may be greater than the depth of the first recess 310R disposed in the first isolation layer 111. This is because the second isolation layer 112 having the relatively wide width may be easily etched compared to the first isolation layer 111.

According to the semiconductor device according to an embodiment, the first protection layer 310 may be positioned on the first recess 310R of the first isolation layer 111, and the second protection layer 320 may be positioned on the second recess 320R of the second isolation layer 112. In this case, the depth of the first protection layer 310 may correspond to the depth of the first recess 310R, and the depth of the second protection layer 320 may correspond to the depth of the second recess 320R. The upper surfaces of the first protection layer 310 and the second protection layer 320 may be disposed to be positioned at the same level.

As such, by forming the protection layer 300 on the isolation layers 110, it is possible to prevent the level of the isolation layers 110 from being reduced in a subsequent process. As the isolation layers 110 are protected by the protection layer 300, the side surface of the active patterns AP may not be exposed. Therefore, in the process of forming the source/drain patterns 150, parasitic source/drain patterns may be prevented from being formed as the side surface of the active patterns AP is used as a seed. In addition, as the isolation layers 110 are protected by the protection layer 300, leakage current generated from the side surface of the active patterns AP may be reduced.

Also, since the isolation layers 110 are protected by the protection layer 300, the gate electrodes 120 may not be filled in the first recess 310R and the second recess 320R. Accordingly, when the gate separation structure 155 is disposed, a short circuit between the adjacent gate electrodes 120 may be easily prevented. Accordingly, the reliability of the semiconductor device may be improved.

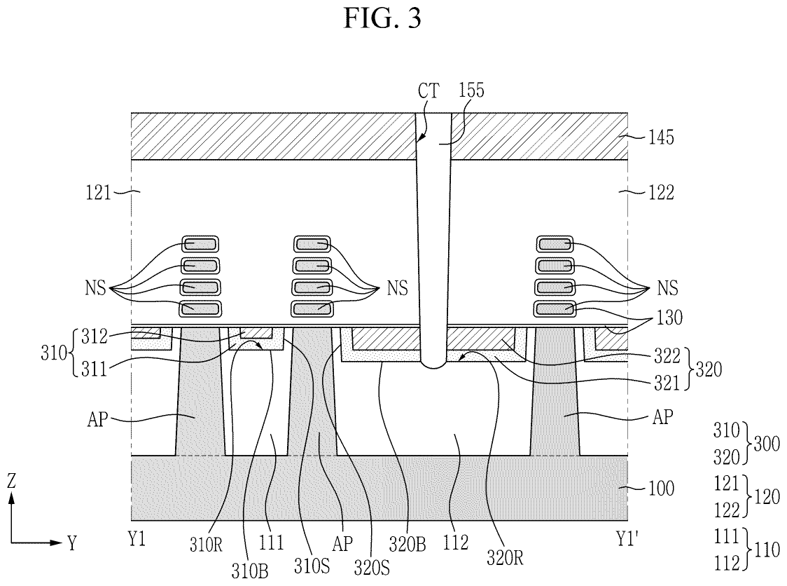

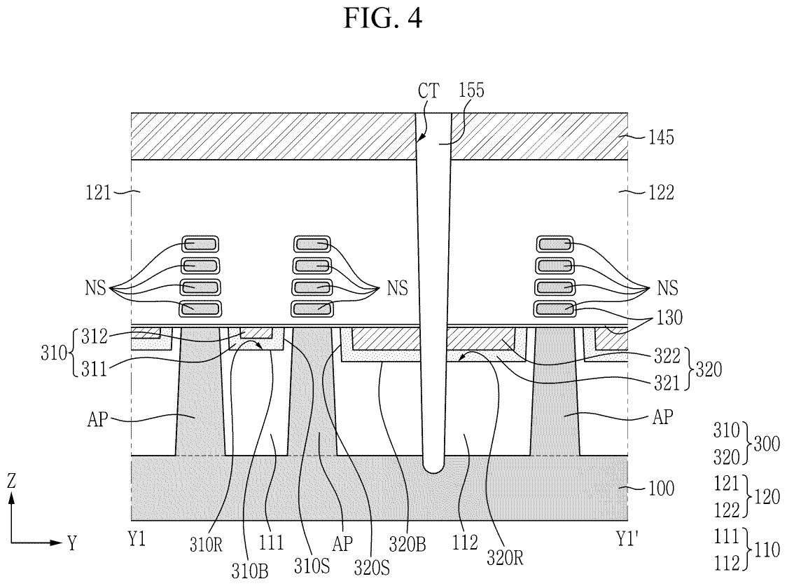

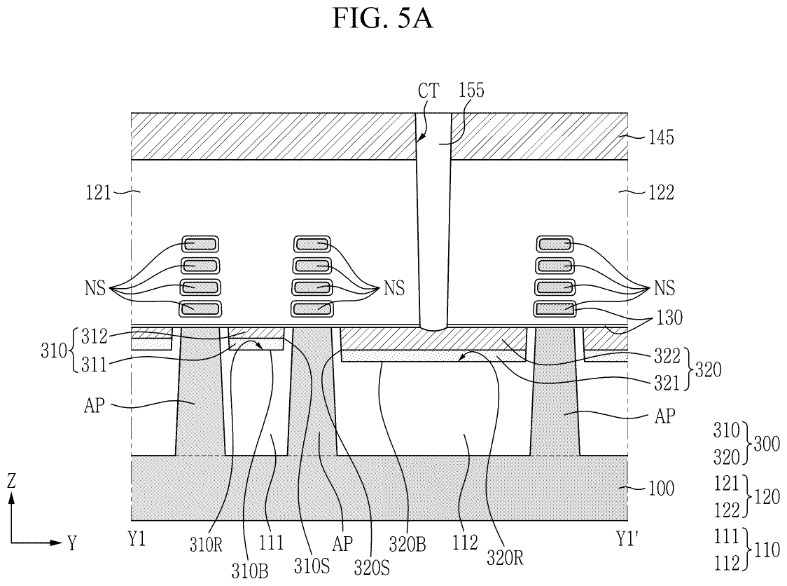

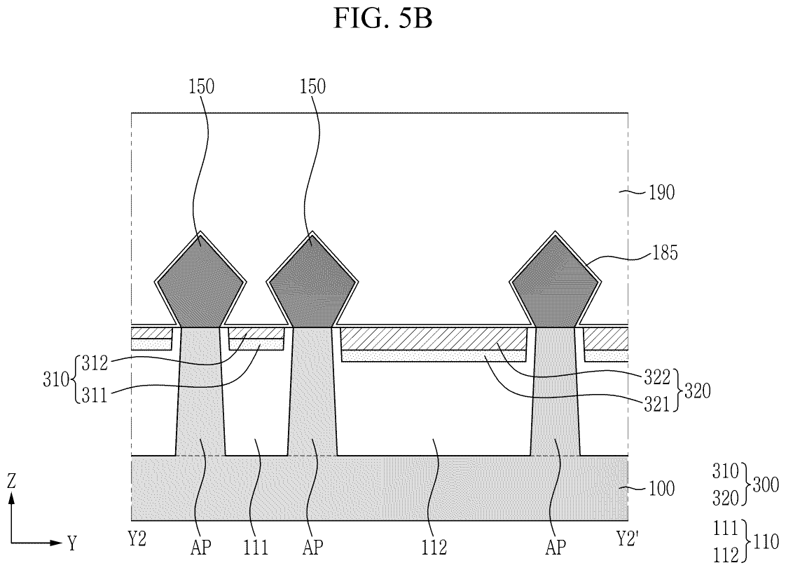

The semiconductor device according to an embodiment is described with reference to FIG. 3 and FIG. 4.

FIG. 3 and FIG. 4 are cross-sectional views showing a semiconductor device according to an embodiment.

An embodiment shown in FIG. 3 and FIG. 4 is the same as most of the embodiment shown in FIG. 1 to FIG. 2D so that the description thereof will be omitted and the difference will be mainly described. The present embodiment differs from the preceding embodiment in that the gate separation structure is recessed into the second isolation layer or the substrate 100, which will be described below.

The semiconductor device according to an embodiment includes a substrate 100, active patterns AP positioned on the substrate 100, isolation layers 110 positioned between the active patterns AP, a protection layer 300 positioned on the isolation layers 110, channel patterns NS positioned on the active patterns AP, gate electrodes 120 surrounding the channel patterns NS, source/drain patterns 150 positioned on both sides of the channel patterns NS, and an interlayer insulating layer 190 positioned on the source/drain patterns 150.

In the previous embodiment, the gate separation structure 155 may be recessed into the second protection insulation layer 322. The bottom surface of the gate separation structure 155 may be positioned at a level similar to that of the second protection insulation layer 322.

Referring to FIG. 3, in the present embodiment, the gate separation structure 155 may be recessed into the second isolation layer 112. Accordingly, the gate separation structure 155 may pass through the second protection insulation layer 322 and the second protection liner 321. The bottom surface of the gate separation structure 155 may be positioned at a lower level than the bottom surface of the second protection liner 321.

Referring to FIG. 4, in the present embodiment, the gate separation structure 155 may be recessed into the substrate 100. Accordingly, the gate separation structure 155 may pass through the second protection insulation layer 322 and the second protection liner 321. Also, the gate separation structure 155 may pass through the second isolation layer 112. The bottom surface of the gate separation structure 155 may be positioned at a lower level than the upper surface of the substrate 100.

Next, the semiconductor device according to an embodiment is described with reference to FIG. 5A and FIG. 5B as follows.

FIG. 5A and FIG. 5B are cross-sectional views showing a semiconductor device according to an embodiment.

An embodiment shown in FIG. 5A and FIG. 5B is the same as most of the embodiment shown in FIG. 1 to FIG. 2D so that the description thereof is omitted and differences are mainly described. In the present embodiment, the shape of the protection liner and the protection insulation layer is different from that of the previous embodiment, and will be described below.

As shown in FIG. 5A and FIG. 5B, a semiconductor device according to an embodiment includes a substrate 100, active patterns AP positioned on the substrate 100, isolation layers 110 positioned between the active patterns AP, a protection layer 300 positioned on the isolation layers 110, channel patterns NS positioned on the active patterns AP, gate electrodes 120 surrounding the channel patterns NS, source/drain patterns 150 positioned on both sides of the channel patterns NS, and an interlayer insulating layer 190 positioned on the source/drain patterns 150.

In the above embodiment, the first protection liner 311 may be positioned in the first recess 310R on the first isolation layer 111 and may extend along the profile of the first recess 310R. The first protection liner 311 may extend along the bottom surface 310B of the first recess 310R and the side surface 310S of the first recess 310R. In addition, the second protection liner 321 may be positioned in the second recess 320R on the second isolation layer 112 and extend along the profile of the second recess 320R. The second protection liner 321 may extend along the bottom surface 320B of the second recess 320R and the side surface 320S of the second recess 320R.

In addition, in the preceding embodiment, the first protection insulation layer 312 may be positioned on the first protection liner 311 within the first recess 310R such that the first protection liner 311 covers side surfaces of the first protection insulation layer 312. In addition, the second protection insulation layer 322 may be positioned on the second protection liner 321 within the second recess 320R such that the second protection liner 321 covers side surfaces of the second protection insulation layer 322. In this case, the first protection insulation layer 312 may not contact the first isolation layer 111, and the second protection insulation layer 322 may not contact the second isolation layer 112.

In the present embodiment, the first protection liner 311 may extend along the bottom surface 310B of the first recess 310R. The first protection liner 311 may not extend along the side surface 310S of the first recess 310R. That is, the first protection liner 311 may not extend in the third direction (the Z direction). In addition, the second protection liner 321 may extend along the bottom surface 320B of the second recess 320R. The second protection liner 321 may not extend along the side surface 320S of the second recess 320R. That is, the second protection liner 321 may not extend in the third direction (the Z direction).

The first protection insulation layer 312 may be positioned on the first protection liner 311 within the first recess 310R. The first protection insulation layer 312 may be disposed on the first protection liner 311 to fill the first recess 310R. The upper surface of the first protection insulation layer 312 may be flat, but is not limited thereto. The first protection insulation layer 312 may be in contact with the first isolation layer 111. The side surface of the first protection insulation layer 312 may be covered by the first isolation layer 111. In addition, the second protection insulation layer 322 may be positioned on the second protection liner 321 within the second recess 320R. The second protection insulation layer 322 may be disposed on the second protection liner 321 to fill the second recess 320R. The upper surface of the second protection insulation layer 322 may be flat, but is not limited thereto. The second protection insulation layer 322 may be in contact with the second isolation layer 112. The side surface of the second protection insulation layer 322 may be covered by the second isolation layer 112.

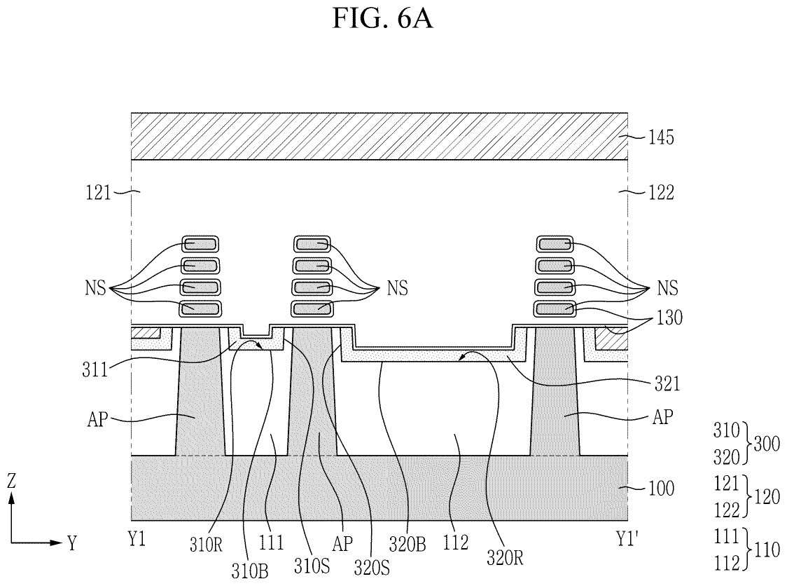

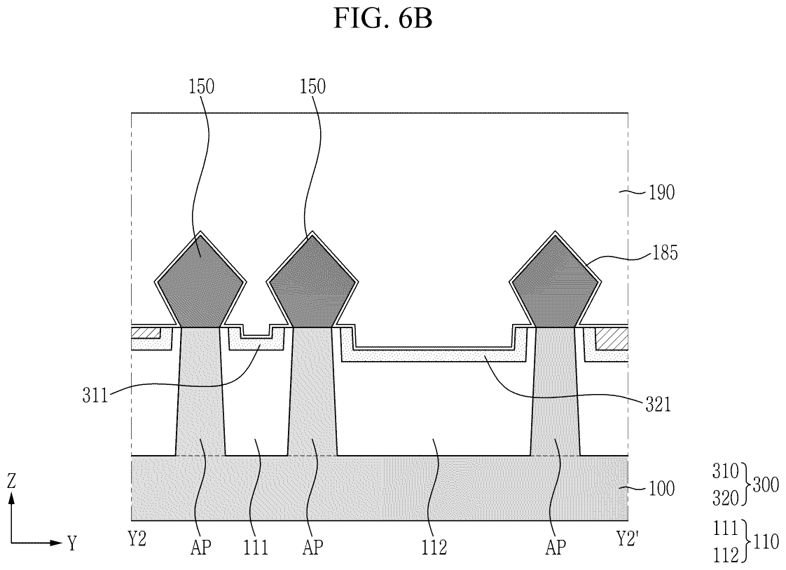

Next, the semiconductor device according to an embodiment is described with reference to FIG. 6A and FIG. 6B as follows.

FIG. 6A and FIG. 6B are cross-sectional views showing a semiconductor device according to an embodiment.

An embodiment shown in FIG. 6A and FIG. 6B is the same as most of the embodiment shown in FIG. 1 to FIG. 2D so that the description thereof will be omitted and differences will be mainly described. In the present embodiment, the protection layer is different from the preceding embodiment in that the protection layer does not include the protection insulation layer.

As shown in FIG. 6A and FIG. 6B, the semiconductor device according to an embodiment includes a substrate 100, active patterns AP positioned on the substrate 100, isolation layers 110 positioned between the active patterns AP, a protection layer 300 positioned on the isolation layers 110, channel patterns NS positioned on the active patterns AP, gate electrodes 120 surrounding the channel patterns NS, source/drain patterns 150 positioned on both sides of the channel patterns NS, and an interlayer insulating layer 190 positioned on the source/drain patterns 150.

In the embodiment shown in FIG. 1 to FIG. 2D, the first protection liner 311 may be positioned in the first recess 310R on the first isolation layer 111 and extend along the profile of the first recess 310R. The first protection liner 311 may extend along the bottom surface 310B of the first recess 310R and the side surface 310S of the first recess 310R. In addition, the second protection liner 321 may be positioned in the second recess 320R on the second isolation layer 112 and extend along the profile of the second recess 320R. The second protection liner 321 may extend along the bottom surface 320B of the second recess 320R and the side surface 320S of the second recess 320R.

The upper surface of the first protection liner 311 may be higher than the upper surface of the second protection liner 321. But, it is not limited thereto, the upper surface of the first protection liner 311 and the upper surface of the second protection liner 321 may be positioned at substantially equivalent levels.

In addition, in the embodiment shown in FIG. 1 to FIG. 2D, the first protection insulation layer 312 may be positioned on the first protection liner 311 within the first recess 310R. The second protection insulation layer 322 may be positioned on the second protection liner 321 in the second recess 320R. In this case, the first protection insulation layer 312 may be not in contact with the first isolation layer 111, and the second protection insulation layer 322 may be not in contact with the second isolation layer 112.

In the present embodiment, the protection layer 300 may include a first protection liner 311 and a second protection liner 321. The protection layer 300 may not include a first protection insulation layer and a second protection insulation layer.

The first protection insulation layer may not be positioned on the first protection liner 311. For example, the gate insulating layer 130 may be positioned on the first protection liner 311. The gate insulating layer 130 may conformally extend along the profile of the first protection liner 311. Also, for example, the etch stop layer 185 may be positioned on the first protection liner 311. The etch stop layer 185 may conformally extend along the profile of the first protection liner 311.

The second protection insulation layer may not be positioned on the second protection liner 321. For example, the gate insulating layer 130 may be positioned on the second protection liner 321. The gate insulating layer 130 may conformally extend along the profile of the second protection liner 321. Also, for example, the etch stop layer 185 may be positioned on the second protection liner 321. The etch stop layer 185 may be conformally extended along the profile of the second protection liner 321.

In this case, the first protection insulation layer and the second protection insulation layer may be omitted in the process of forming the protection layer 300. Alternatively, after forming the first protection insulation layer on the first protection liner 311 and forming the second protection insulation layer on the second protection liner 321, they may be removed as the subsequent process proceeds.

Next, a description of a method of manufacturing a semiconductor device according to an embodiment is described with reference to FIG. 7A to FIG. 17B as follows.

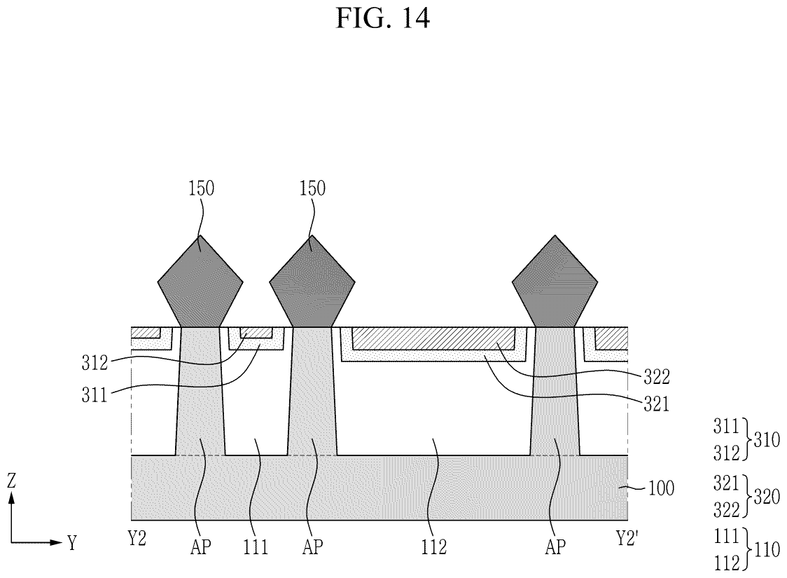

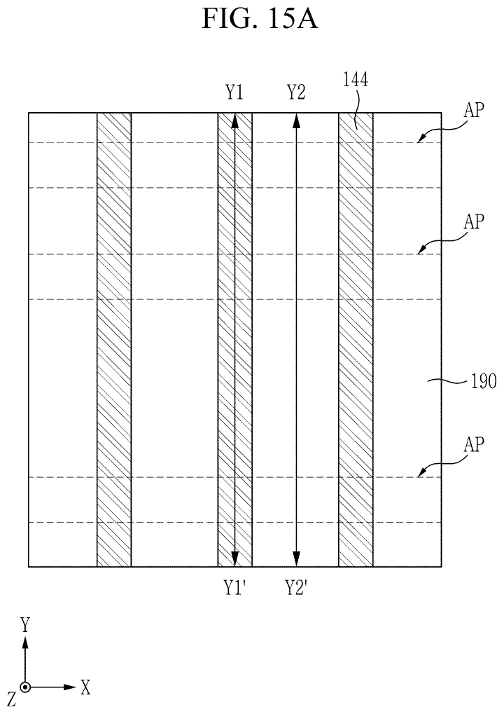

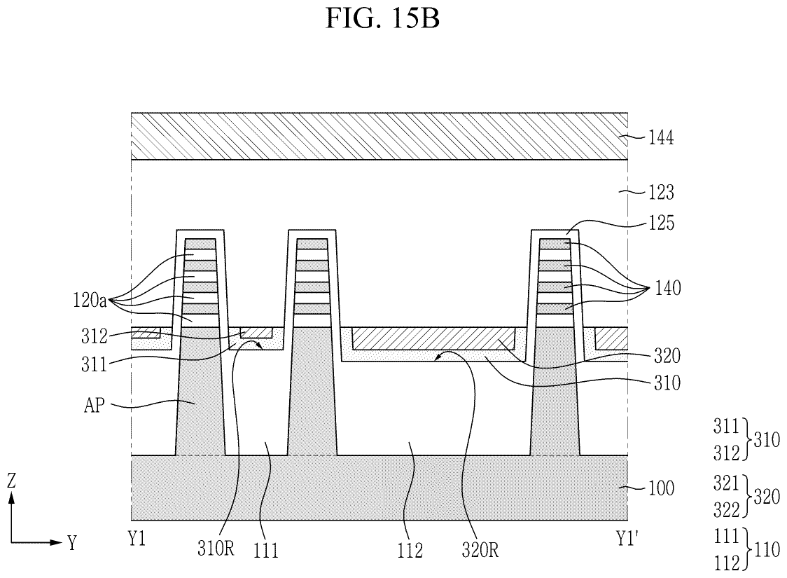

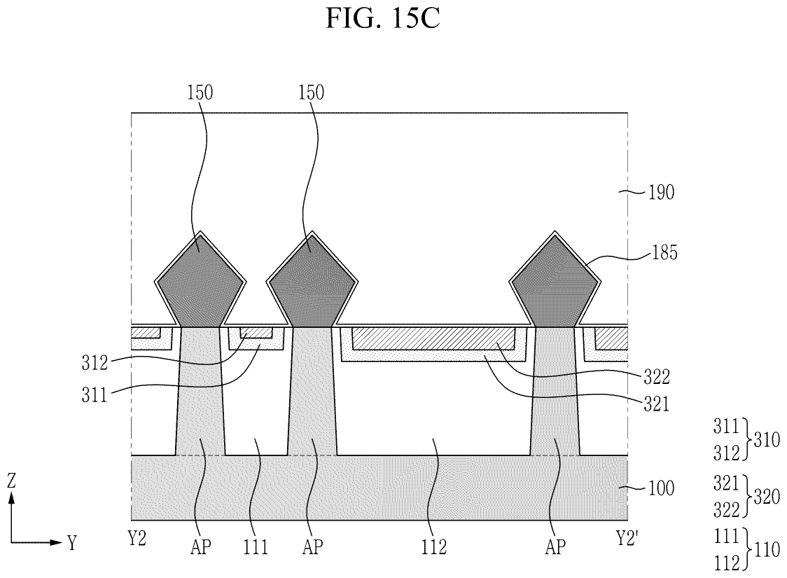

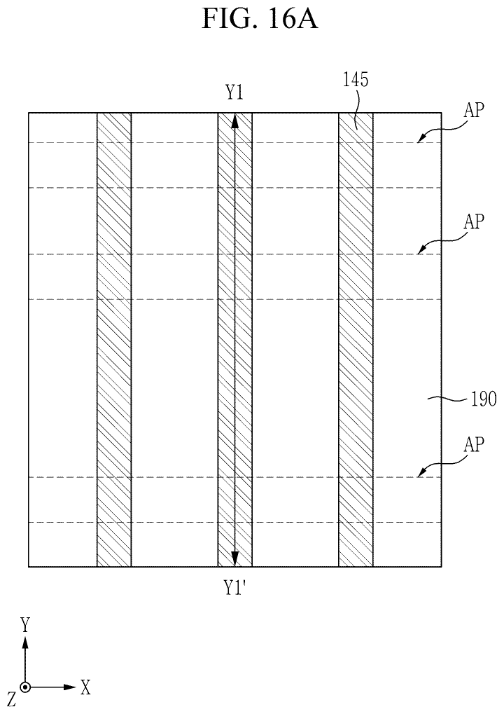

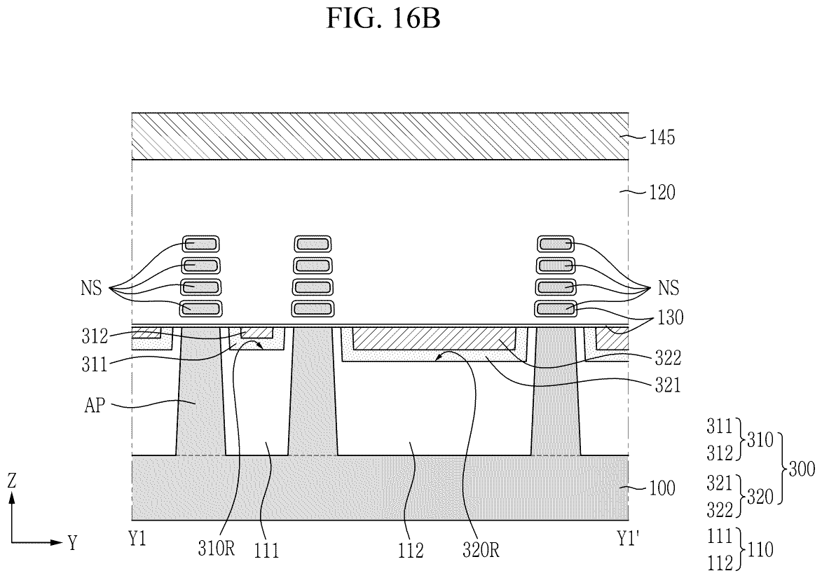

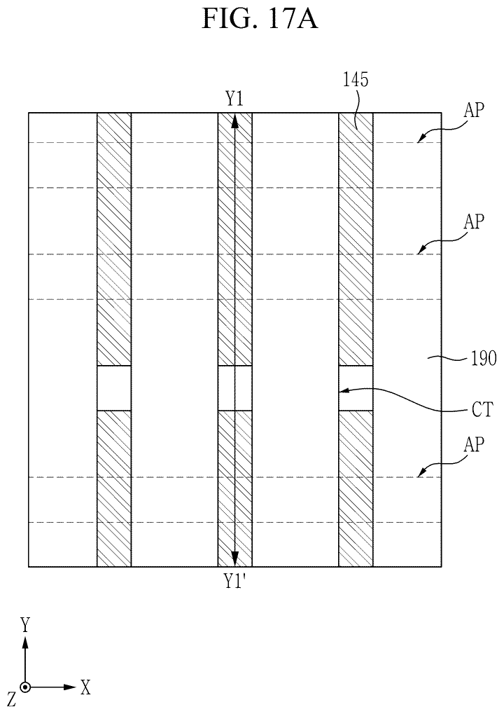

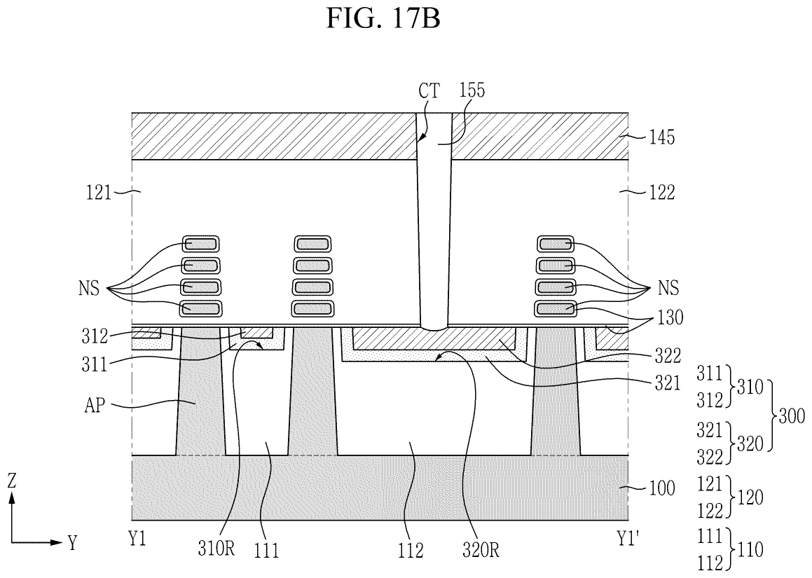

FIG. 7A, FIG. 8A, FIG. 10A, FIG. 12A, FIG. 13A, FIG. 15A, FIG. 16A, and FIG. 17A are plan views sequentially showing a method of manufacturing a semiconductor device according to an embodiment. FIG. 7B, FIG. 8B, FIG. 9, FIG. 10B, FIG. 11, FIG. 12B, FIG. 13B, FIG. 15B, FIG. 16B, and FIG. 17B are cross-sectional views taken a line Y1-Y1′ of each plan view. FIG. 14 and FIG. 15C are cross-sectional views showing a semiconductor device according to an embodiment.

As shown in FIG. 7A and FIG. 7B, a channel pattern structure NSS is formed on a substrate 100. The channel pattern structure NSS includes a plurality of sub-gate sacrificial patterns 120a and a plurality of semiconductor patterns 140 that are alternately stacked.

On the substrate 100, active patterns AP protruding from the upper surface of the substrate 100 may be positioned. The active patterns AP may protrude in the third direction (the Z direction) from the upper surface of the substrate 100. The active patterns AP may be positioned to be spaced apart from each other along the second direction (the Y direction). The active patterns AP may extend along the first direction (the X direction).

The distance between the active patterns AP may not be constant. For example, while the first active pattern, the second active pattern, and the third active pattern extend along the first direction (the X direction), they may be disposed to be spaced in the second direction (the Y direction). At this time, the distance between the first active pattern and the second active pattern may be different from the distance between the second active pattern and the third active pattern. However, it is not limited thereto, and the distance between active patterns APs may be constant.

The channel pattern structure NSS may be positioned on the active patterns AP. The channel pattern structure NSS may be in contact with the active patterns AP.

A plurality of sub-gate sacrificial patterns 120a and a plurality of semiconductor patterns 140 may be sequentially accumulated to form the channel pattern structure NSS. Any one gate sacrificial pattern among a plurality of sub-gate sacrificial patterns 120a may be positioned on the active patterns AP and in contact with the active patterns AP. At this time, it is shown that four sub-gate sacrificial patterns 120a and four semiconductor patterns 140 are alternately stacked, but this is only one example and may be variously changed. That is, the number of layers of the sub-gate sacrificial pattern 120a or the number of layers of the semiconductor pattern 140 may be less than 4 or more than 4, respectively.

The channel pattern structure NSS may be formed using an epitaxial growth method. For example, a layer made of silicon germanium (SiGe) and a layer made of silicon (Si) are alternately formed using the epitaxial growth method, and a hard mask pattern 510 is formed thereon. The hard mask pattern 510 may be formed of silicon nitride (SiN). The channel pattern structure NSS may be formed by patterning the layer made of silicon germanium and the layer made of silicon by using the hard mask pattern 510 as a mask. Accordingly, the hard mask pattern 510 may be positioned on the channel pattern structure NSS. In this case, a plurality of sub-gate sacrificial patterns 120a may be made of silicon germanium, and a plurality of semiconductor patterns 140 may be made of silicon. However, it is not limited thereto, and the materials of a plurality of sub-gate sacrificial patterns 120a and semiconductor patterns 140 may be variously changed.

On a plane, a plurality of channel pattern structure NSS may extend in the first direction (the X direction). A plurality of channel pattern structures NSS may be positioned on the substrate 100.

In addition, a preliminary isolation layer 105 is formed between a plurality of channel pattern structures NSS.

A preliminary isolation layer 105 is formed on the substrate 100 on which the channel pattern structure NSS is formed. The preliminary isolation layer 105 may be an insulating material and may be made of a material that may well fill the empty space. For example, the preliminary isolation layer 105 may include silicon oxide (SiO2), silicon nitride (SiN), silicon oxynitride (SiON), or a combination thereof. Next, the chemical mechanical polishing (CMP) process may be performed to planarize the upper surface of the preliminary isolation layer 105. Accordingly, the upper surface of the preliminary isolation layer 105 and the upper surface of the hard mask pattern 510 may be made flat.

As shown in FIG. 8A and FIG. 8B, a first isolation layer 111 and a second isolation layer 112 may be formed by removing the hard mask pattern 510 and removing at least a part of the preliminary isolation layer 105.

First, the channel pattern structure NSS may be made of a material having an etch selectivity different from that of the hard mask pattern 510. Accordingly, even if the upper surface of the channel pattern structure NSS is exposed as the hard mask pattern 510 is removed, the channel pattern structure NSS may not be removed.

Subsequently, an etching process is performed to remove at least a portion of the preliminary isolation layer 105, thereby reducing the thickness of the preliminary isolation layer 105. The preliminary isolation layer 105 may be made of a material having an etch selectivity different from that of the channel pattern structure NSS. Therefore, in the process of removing the preliminary isolation layer 105, the channel pattern structure NSS may not be removed.

A portion of the preliminary isolation layer 105 may be removed and then separated into a first isolation layer 111 and a second isolation layer 112. The first isolation layer 111 and the second isolation layer 112 may be positioned at the same level as the active patterns AP, respectively. In this case, the second width D2 of the second isolation layer 112 may be wider than the first width D1 of the first isolation layer 111. The distance between the active patterns AP positioned on both sides of the second isolation layer 112 may be greater than the distance between the active patterns AP positioned on both sides of the first isolation layer 111. Also, as described above, since the second width D2 of the second isolation layer 112 is wider than the first width D1 of the first isolation layer 111, the second isolation layer 112 may be etched more easily than the first isolation layer 111. Accordingly, the first height H1 according to the third direction (the Z direction) of the first isolation layer 111 may be higher than the second height H2 according to the third direction (the Z direction) of the second isolation layer 112.

A first recess 310R may be formed in the first isolation layer 111 and a second recess 320R may be formed in the second isolation layer 112. In this case, the width of the second recess 320R may be wider than the width of the first recess 310R, and the depth of the second recess 320R may be deeper than the depth of the first recess 310R. This may be due to a characteristic of the process of removing a part of the preliminary isolation layer 105. For example, since the second isolation layer 112 may have the relatively wider width than the first isolation layer 111, the second isolation layer 112 may be easily etched compared to the first isolation layer 111. Therefore, since the second isolation layer 112 may be etched with the wider width and depth than the first isolation layer 111, the width of the second recess 320R formed by etching the second isolation layer 112 may be wider than the width of the first recess 310R formed by etching the first isolation layer 111, and the depth of the second recess 320R may be deeper than the depth of the first recess 310R.

In this case, a sacrificial insulation layer 125 may be formed on the channel pattern structure NSS. The sacrificial insulation layer 125 may be formed to surround the channel pattern structure NSS. The sacrificial insulation layer 125 may be conformally formed along the profile of the channel pattern structure NSS. The sacrificial insulation layer 125 may include the same material (e.g., silicon oxide SiO2) as the first isolation layer 111 and the second isolation layer 112. In this case, the sacrificial insulation layer 125 may be integrally formed by being in contact with the first isolation layer 111 and the second isolation layer 112 without a boundary surface.

As shown in FIG. 9, a preliminary protection liner 301 may be formed on the sacrificial insulation layer 125, the first isolation layer 111, and the second isolation layer 112. The preliminary protection liner 301 may be conformally formed on the surfaces of the first recess 310R of the first isolation layer 111, the second recess 320R of the second isolation layer 112, and the sacrificial insulation layer 125. Accordingly, the preliminary protection liner 301 may be formed along the profiles of the first recess 310R and the second recess 320R.

The preliminary protection liner 301 may include a material having different etch selectivity from that of the isolation layers 110. The preliminary protection liner 301 may include a material having different channel patterns NS and etch selectivity. For example, the preliminary protection liner 301 may include silicon nitride (SiN).

As shown in FIG. 10A and FIG. 10B, a preliminary protection insulation layer 302 may be formed on the preliminary protection liner 301. The preliminary protection insulation layer 302 is an insulating material and may be made of a material that may well fill the empty space. For example, the preliminary protection insulation layer 302 may include silicon oxide SiO2, silicon oxynitride (SiON) or a combination thereof. Subsequently, a chemical mechanical polishing (CMP) process may be performed to planarize the upper surface of the preliminary protection insulation layer 302. Accordingly, the upper surface of the preliminary protection insulation layer 302 and the upper surface of the preliminary protection liner 301 may be formed flat.

As shown in FIG. 11, an etching process proceeds to remove a part of the preliminary protection insulation layer 302. The etching process may be performed by a dry etching method. For example, the dry etching may be performed using hydrofluoric acid (HF), but is not limited thereto. The preliminary protection insulation layer 302 may include a material having different etch selectivity from that of the preliminary protection liner 301. The preliminary protection insulation layer 302, for example, may include silicon oxide (SiO2), silicon oxynitride (SiON), or a combination thereof. Therefore, even if the side surface of the preliminary protection liner 301 is exposed as the preliminary protection insulation layer 302 is etched, the side surface and upper surface of the preliminary protection liner 301 may not be removed.

As a part of the preliminary protection insulation layer 302 is removed, a first protection insulation layer 312 and a second protection insulation layer 322 separated from each other may be formed. The upper surface of the first protection insulation layer 312 and the upper surface of the second protection insulation layer 322 may be positioned at similar levels. As another example, the upper surface of the second protection insulation layer 322 may be lower than the upper part of the first protection insulation layer 312.

As shown in FIG. 12A and FIG. 12B, the first protection insulation layer 312 and the second protection insulation layer 322 are used as a mask to perform an etching process to remove the preliminary protection liner 301. The etching process may be performed by a dry etching method. For example, the dry etching may be performed using phosphoric acid (H3PO4), but is not limited thereto.

The preliminary protection liner 301 may include a material having different etch selectivity from the first protection insulation layer 312 and the second protection insulation layer 322. Also, the preliminary protection liner 301 may include a material having different etch selectivity from the sacrificial insulation layer 125. The preliminary protection liner 301, for example, may include silicon nitride (SiN).

Accordingly, even if the upper and side surfaces of the sacrificial insulation layer 125 are exposed as the preliminary protection liner 301 is etched, the sacrificial insulation layer 125 may not be removed. Alternatively, the preliminary protection liner 301 may include a material having different etch selectivity from that of the channel patterns NS. In this case, the preliminary protection liner 301 may include a material having different etch selectivity from that of the sub-gate sacrificial pattern 120a and the semiconductor pattern 140. As a part of the preliminary protection liner 301 is removed, a first protection liner 311 and a second protection liner 321 separated from each other may be formed. The first protection liner 311 may be positioned at the same level as the upper surface of the first protection insulation layer 312, and the second protection liner 321 may be positioned at the same level as the upper surface of the second protection insulation layer 322. In addition, the first protection liner 311 and the second protection liner 321 may be positioned at the same level. Accordingly, the first protection liner 311 may have a shape extending along the profile of the first recess 310R within the first recess 310R. The second protection liner 321 may have a shape extending along the profile of the second recess 320R within the second recess 320R.

In summary, the first protection layer 310 may be formed to fill the first recess 310R, and the second protection layer 320 may be formed to fill the second recess 320R. The upper surfaces of the first protection layer 310 and the second protection layer 320 may be positioned at the same level. That is, since the first protection layer 310 is formed on the first isolation layer 111 and the second protection layer 320 is formed on the second isolation layer 112, it is possible to prevent the level of the first isolation layer 111 and the second isolation layer 112 from being reduced in a subsequent process.

As shown in FIG. 13A and FIG. 13B, a main gate sacrificial pattern 123 and a capping layer 144 are formed on the channel pattern structure NSS.

On the substrate 100 on which the channel pattern structure NSS is disposed, after sequentially stacking a material layer for forming the main gate sacrificial pattern 123 and a material layer for forming the capping layer 144, the material layer for forming the capping layer 144 is patterned to form the capping layer 144. Subsequently, the main gate sacrificial pattern 123 is formed by patterning the material layer for forming the main gate sacrificial pattern 123 by using the capping layer 144 as a mask. Accordingly, the capping layer 144 may have a shape covering the upper surface of the main gate sacrificial pattern 123, and the main gate sacrificial pattern 123 may have a shape similar to that of the capping layer 144 on a plane.

The main gate sacrificial pattern 123 may not be in contact with the substrate 100. A protection layer 300 may be positioned between the substrate 100 and the main gate sacrificial pattern 123.

The main gate sacrificial pattern 123 may be positioned between the protection layer 300 and the capping layer 144. The main gate sacrificial pattern 123 may be positioned directly above the first protection insulation layer 312 and the second protection insulation layer 322. Therefore, the main gate sacrificial pattern 123 may be not in contact with the first isolation layer 111 and the second isolation layer 112. In addition, the main gate sacrificial pattern 123 may not be positioned on the side surface of the active patterns AP. The part of the main gate sacrificial pattern 123 positioned on the first protection insulation layer 312 and the part of the main gate sacrificial pattern 123 positioned on the second protection insulation layer 322 may be positioned at the similar level.

The main gate sacrificial pattern 123 may be positioned between the sacrificial insulation layer 125 and the capping layer 144. The main gate sacrificial pattern 123 may be positioned directly above the sacrificial insulation layer 125. However, it is not limited thereto, and the main gate sacrificial pattern 123 may be positioned directly above the semiconductor pattern 140.

On a plane, the elongation direction of the main gate sacrificial pattern 123 and the capping layer 144 may intersect with the elongation direction of the channel pattern structure NSS. The main gate sacrificial pattern 123 and the capping layer 144 may extend in the second direction (the Y direction) perpendicular to the first direction (the X direction). A plurality of main gate sacrificial pattern 123 may be positioned to be spaced apart by a predetermined interval along the first direction (the X direction).

The main gate sacrificial pattern 123 may include polysilicon, and the capping layer 144 may include silicon nitride (SiN). However, it is not limited thereto, and the materials of the main gate sacrificial pattern 123 and the capping layer 144 may be variously changed. In addition, gate spacers may be further formed on both sides of the main gate sacrificial pattern 123 and the capping layer 144. The gate spacer may be formed to cover side surfaces of the main gate sacrificial pattern 123 and the capping layer 144. The gate spacer, for example, may include at least one of silicon nitride (SiN), silicon oxynitride (SiON), silicon oxide (SiO2), silicon carbonate nitride (SiOCN), silicon boronnitride (SiBN), silicon oxyboronitride (SiOBN), silicon carbonate (SiOC) and combination thereof.

As shown in FIG. 14, by using the main gate sacrificial pattern 123 and the capping layer 144 as a mask, at least a part of the channel pattern structure NSS is etched to form a source/drain recess. In this case, the semiconductor pattern 140 and a plurality of sub-gate sacrificial patterns 120a may be removed while being sequentially exposed. The side surface of the channel pattern structure NSS may be exposed to the outside by the formation of the source/drain recess. In addition, the upper surface of active patterns AP may be exposed to the outside.

Accordingly, a plurality of semiconductor patterns 140 may be separated to form channel patterns (NS in FIG. 15B). The channel patterns (NS in FIG. 15B) may be positioned on either side of the source/drain recess. The structure in which the channel patterns NS and a plurality of sub-gate sacrificial patterns 120a are alternately stacked may be disposed. At this time, the length of each channel pattern (NS in FIG. 15B) may be different or the same.

Subsequently, source/drain patterns 150 are formed in the source/drain recess. The source/drain patterns 150 may be formed using an epitaxial growth method. At this time, the source/drain recess inner wall may be used as a seed. The source/drain recess inner wall consists of the channel patterns NS, the side surface of a plurality of sub-gate sacrificial patterns 120a, and the upper surface of the active patterns AP. The source/drain patterns 150 may include silicon (Si) or silicon germanium (SiGe). However, it is not limited thereto, and the material of the source/drain patterns 150 may be variously changed.

As shown in FIG. 15A, FIG. 15B, and FIG. 15C, an interlayer insulating layer 190 is formed on the source/drain patterns 150. The interlayer insulating layer 190 may be formed to fill a region between a plurality of main gate sacrificial patterns 123. The interlayer insulating layer 190 may be formed to cover the upper and side surfaces of the source/drain patterns 150. The interlayer insulating layer 190 is an insulating material and may be made of a material that may well fill an empty space. For example, the interlayer insulating layer 190 may include at least one among silicon oxide (SiO2), silicon nitride (SiN), silicon oxynitride (SiON), and low dielectric constant (low-k) material. The low dielectric constant (low-k) material, for example, may include Fluorinated TetraEthylOrthoSilicate (FTEOS), HydrogenSilsesQuioxane (HSQ), Bis-benzoCycloButene (BCB), TetraMethylOrthoSilicate (TMOS), or combination thereof, but it is not limited thereto.

The interlayer insulating layer 190 may be positioned on the previously disposed protection layer 300. The interlayer insulating layer 190 may be made of the same material as the isolation layers 110, the first protection insulation layer 312, or the second protection insulation layer 322 previously formed. However, it is not limited thereto, and may be made of a material different from that of the isolation layers 110, the first protection insulation layer 312, or the second protection insulation layer 322.

Prior to forming the interlayer insulating layer 190, an etch stop layer 185 may be formed on the upper surface of the protection layer 300, the sidewall of the gate spacer 142, and the upper surface of the source/drain patterns 150. The etch stop layer 185, for example, may include at least one of silicon nitride (SiN), silicon oxynitride (SiON), silicon carbonate nitride (SiOCN), silicon boronnitride (SiBN), silicon oxyboronitride (SiOBN), silicon carbonate (SiOC), and combination thereof. The interlayer insulating layer 190 may be positioned on the etch stop layer 185 and may be formed to fill the space.

Subsequently, the upper surface of the interlayer insulating layer 190 is planarized using a chemical mechanical polishing (CMP) process. Accordingly, the upper surface of the interlayer insulating layer 190 and the upper surface of the capping layer 144 may be flat.

As shown in FIG. 16A, and FIG. 16B, the capping layer 144, the main gate sacrificial pattern 123, the sacrificial insulation layer 125, and a plurality of sub-gate sacrificial patterns 120a are removed.

If the capping layer 144 is removed, the main gate sacrificial pattern 123 may be exposed to the outside. The exposed main gate sacrificial pattern 123 may be removed using an etching process. As the main gate sacrificial pattern 123 is removed, the sacrificial insulation layer 125 may be exposed to the outside. The exposed sacrificial insulation layer 125 may be removed using an etching process. As the sacrificial insulation layer 125 is removed, a plurality of sub-gate sacrificial patterns 120a may be exposed to the outside. A plurality of exposed sub-gate sacrificial patterns 120a may be removed using an etching process.

Next, gate electrodes 120 are formed in the space where the main gate sacrificial pattern 123 and a plurality of sub-gate sacrificial patterns 120a are removed.

Prior to forming the gate electrodes 120, a gate insulating layer 130 may be formed. The gate insulating layer 130 may be conformally formed on the surface exposed by the space from which the main gate sacrificial pattern 123 and a plurality of sub-gate sacrificial patterns 120a are removed. That is, the gate insulating layer 130 may be formed between the gate electrodes 120 and the sub-gate sacrificial pattern 120a.

Subsequently, gate electrodes 120 may be formed on the gate insulating layer 130.

The gate electrodes 120 are positioned in the space from which a plurality of sub-gate sacrificial patterns 120a are removed. The gate electrodes 120 are positioned on the gate insulating layer 130 and are formed to fill the space. For example, each gate electrode 120 is positioned at a portion where each sub-gate sacrificial pattern 120a is removed. Therefore, the channel patterns NS and the gate electrodes 120 may have a structure in which they are alternately stacked. Accordingly, the gate insulating layer 130 may be positioned between the gate electrodes 120 and each of the channel patterns NS. In addition, the gate insulating layer 130 may be positioned between the gate electrodes 120 and the source/drain patterns 150.

In addition, the gate electrodes 120 are positioned within the space where the main gate sacrificial pattern 123 is removed. The gate electrodes 120 may extend along the second direction (the Y direction).

The gate electrodes 120 may be formed using an atomic layer deposition (ALD) process or a chemical vapor deposition (CVD) process. The gate electrodes 120 may include doped polysilicon, a metal, conductive metal nitride, a conductive metal carbide, or a combination thereof. However, this is just an example, and the material of the gate electrodes 120 is not limited thereto.

Next, a capping layer 145 is formed on the gate electrodes 120. The capping layer 145 may cover the upper surface of the gate electrodes 120 and may have a similar shape to that of the gate electrodes 120 on a plane. The upper surface of the capping layer 145 and the upper surface of the interlayer insulating layer 190 may be disposed flat.

As shown in FIG. 17A, and FIG. 17B, a portion of the gate electrodes 120 and the capping layer 145 is removed to form a gate separation hole CT.

The gate separation hole CT may be disposed on the second isolation layer 112. A plurality of gate separation hole CTs may be disposed to be spaced apart from each other along the first direction (the X direction), but is not limited thereto. Through the gate separation hole CT, the gate electrodes 120 may be separated into a first gate electrode 121 and a second gate electrode 122. In the semiconductor device according to embodiments, one gate separation hole CT may divide a pair of a first gate electrode 121 and a second gate electrode 122. That is, the short-circuiting between the adjacent gate electrodes 120 may be prevented by the gate separation hole CT. The gate separation hole CT may be recessed into the second protection insulation layer 322, but is not limited thereto.

Next, referring to FIG. 2A to FIG. 2D, an insulating material may be filled in the gate separation hole CT and a chemical mechanical polishing (CMP) process may be performed to planarize the upper surface of the gate separation hole CT and the capping layer 145. Accordingly, a gate separation structure 155 may be formed, and the semiconductor device of FIG. 2A to FIG. 2D may be formed.

According to the semiconductor device according to an embodiment, the first isolation layer 111 and the second isolation layer 112 may have different widths. In addition, recesses having different widths and different depths may be disposed in the first isolation layer 111 and the second isolation layer 112, respectively. For example, the depth of the second recess 320R disposed in the second isolation layer 112 may be greater than the depth of the first recess 310R disposed in the first isolation layer 111. This is because the second isolation layer 112 having the relatively wide width may be easily etched compared to the first isolation layer 111.

As such, by forming the protection layer 300 on the isolation layers 110, it is possible to prevent the level of the isolation layers 110 from being reduced in a subsequent process. As the isolation layers 110 are protected by the protection layer 300, the side surface of the active patterns AP may not be exposed. Therefore, in the process of forming the source/drain patterns, the parasitic source/drain pattern may be prevented from being formed using the side surface of the active patterns AP as a seed. In addition, as the isolation layers 110 are protected by the protection layer 300, leakage current generated from the side surface of the active patterns AP may be reduced. Also, since the isolation layers 110 are protected by the protection layer 300, the gate electrodes 120 may not be filled in the first recess 310R and the second recess 320R. Therefore, when the gate separation structure 155 is formed, a short circuit between the adjacent gate electrodes 120 may be easily prevented. Accordingly, the reliability of the semiconductor device may be improved.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

100: substrate
AP: active patterns
NS: channel patterns
110: isolation layers
111: first isolation layer
112: second isolation layer
310R: first recess
320R: second recess
300: protection layer
310: first protection layer
320: second protection layer
311: first protection liner
312: first protection insulation layer
321: second protection liner
322: second protection insulation layer
120: gate electrode
155: gate separation structure
150: source/drain patterns

What is claimed is:

1. A semiconductor device comprising:
a substrate extending a first direction and a second direction perpendicular to the first direction;
active patterns positioned on the substrate;
a first isolation layer and a second isolation layer positioned between the active patterns;
a first protection liner positioned on the first isolation layer;
a second protection liner positioned on the second isolation layer;
channel patterns positioned on the active patterns;
source/drain patterns positioned on both sides of the channel patterns; and
a first gate electrode positioned above the first protection liner and the second protection liner, and surrounding the channel patterns,
wherein the first isolation layer has a first width in the second direction,
the second isolation layer has a second width, in the second direction, wider than the first width, and
a first height from the substrate to the first protection liner is greater than a second height from the substrate to the second protection liner.

2. The semiconductor device of claim 1, further comprising:
a first recess disposed on the upper surface of the first isolation layer; and
a second recess disposed on the upper surface of the second isolation layer,
wherein the first protection liner covers the bottom surface and the side surface of the first recess, and
the second protection liner covers the bottom surface and the side surface of the second recess.

3. The semiconductor device of claim 2, wherein
the depth of the second recess is greater than the depth of the first recess.

4. The semiconductor device of claim 2, wherein
a first protection insulation layer is positioned on the first protection liner within the first recess, and
a second protection insulation layer is positioned on the second protection liner within the second recess.

5. The semiconductor device of claim 4, wherein
in the second direction, the width of the second protection insulation layer is wider than the width of the first protection insulation layer.

6. The semiconductor device of claim 4, wherein
the depth of the second protection insulation layer is greater than the depth of the first protection insulation layer.

7. The semiconductor device of claim 4, wherein
etch selectivity of the first protection insulation layer and the first protection liner are different.

8. The semiconductor device of claim 1, wherein
in the second direction, the width of the second protection liner is greater than the width of the first protection liner.

9. The semiconductor device of claim 1, wherein
the first protection liner and the second protection liner include a silicon nitride.

10. The semiconductor device of claim 1, wherein:
a second gate electrode is spaced apart from the first gate electrode and positioned on the second protection liner; and
a gate separation structure is positioned between the first gate electrode and the second gate electrode.

11. The semiconductor device of claim 10, wherein
the gate separation structure is positioned on the second protection liner.

12. The semiconductor device of claim 10, further comprising
a gate insulating layer surrounding the channel patterns and positioned between the channel patterns and the first gate electrode.

13. A semiconductor device comprising:
a substrate extending a first direction and a second direction perpendicular to the first direction;
active patterns positioned on the substrate;
isolation layers positioned between the active patterns;
a protection layer positioned on the isolation layer;
channel patterns positioned on the active patterns;
source/drain patterns positioned on both sides of the channel patterns; and
a first gate electrode positioned on the active patterns and the protection layer, and surrounding the channel patterns.

14. The semiconductor device of claim 13, wherein
the isolation layers include a first isolation layer having a first width and a second isolation layer having a second width wider than the first width in the second direction,
the protection layer includes a first protection layer positioned on the first isolation layer and a second protection layer positioned on the second isolation layer, and
the depth of the second protection layer is greater than the depth of the first protection layer.

15. The semiconductor device of claim 14, wherein
the width of the second protection layer is greater than the width of the first protection layer in the second direction.

16. The semiconductor device of claim 14, wherein
the first protection layer includes a first protection liner disposed on the upper surface of the first isolation layer and a first protection insulation layer positioned on the first protection liner, and
the second protection layer includes a second protection liner disposed on the upper surface of the second isolation layer and a second protection insulation layer positioned on the second protection liner.

17. The semiconductor device of claim 16, wherein
the width of the second protection liner is wider than the width of the first protection liner in the second direction.

18. A semiconductor device comprising:
a substrate extending a first direction and a second direction perpendicular to the first direction;
active patterns positioned on the substrate;
a first isolation layer and a second isolation layer positioned between the active patterns;
a first recess disposed in the upper surface of the first isolation layer;
a second recess disposed in the upper surface of the second isolation layer;
a first protection liner covering the bottom surface of the first recess;
a second protection liner covering the bottom surface of the second recess;
channel patterns positioned on the active patterns;
source/drain patterns positioned on both sides of the channel patterns; and
a first gate electrode positioned above the first protection liner and the second protection liner, and surrounding the channel patterns,
wherein the first isolation layer has a first width in the second direction,
the second isolation layer has a second width, in the second direction, wider than the first width, and
the depth of the second recess is greater than the depth of the first recess.

19. The semiconductor device of claim 18, wherein
a first protection insulation layer is positioned on the first protection liner within the first recess, and
a second protection insulation layer is positioned on the second protection liner within the second recess.

20. The semiconductor device of claim 19, wherein
the depth of the second protection insulation layer is greater than the depth of the first protection insulation layer.
